(19) United States
(12) Patent Application Publication
(10) Pub. No.: US 2026/0068480 A1
(43) Pub. Date: Mar. 5, 2026

(54) DISPLAY DEVICE

(71) Applicant: LG Display Co., Ltd., Seoul (KR)

(72) Inventors: Minki KIM, Anyang-si (KR); Hoonsok SON, Seoul (KR); Hakmin LEE, Paju-si (KR)

(73) Assignee: LG Display Co., Ltd., Seoul (KR)

(21) Appl. No.: 19/274,742

(22) Filed: Jul. 21, 2025

(30) Foreign Application Priority Data
Sep. 4, 2024 (KR) 10-2024-0120265

(51) Int. Cl. H10K 59/80; H10K 59/35

(52) U.S. Cl. CPC H10K 59/80518; H10K 59/353; H10K 59/876

(57) ABSTRACT

Disclosed is a display device including a first substrate having a plurality of sub-pixels areas corresponding to a plurality of sub-pixels. A first electrode is disposed on the substrate within each sub-pixel, and a light-emissive layer is disposed on each first electrode. A second electrode is disposed on the light-emissive layer. Reflective electrodes are also disposed on the substrate within the respective sub-pixels, and the reflective electrodes have different thicknesses among the sub-pixels. The variation in thickness allows the display device to control the emission characteristics of each sub-pixel, facilitating color differentiation without using a color filter.

### CROSS-REFERENCE TO RELATED APPLICATION

This application claims priority from Korean Patent Application No. 10-2024-0120265 filed on Sep. 4, 2024, in the Korean Intellectual Property Office, and all the benefits accruing therefrom under 35 U.S.C. 119, the contents of which in its entirety are herein incorporated by reference.

### BACKGROUND

### Technical Field

The present disclosure relates to a display device for displaying an image, and more specifically, to a display device and a display panel capable of constructing dense pixels to realize the ultra-high resolution without using the expensive equipment through various experiments.

### Description of Related Art

A display device is applied to various electronic devices such as a TV, a mobile phone, a laptop, and a tablet. To this end, research to develop a thinner, lighter, and less power consuming display device is being conducted.

Recently, as a demand for a head mounted display (HMD) including the display device increases, research thereon is also increasing. The head mounted display is an image display device that uses a glasses or helmet-type device to allow an image to be focused at a close distance to user's eyes.

The head mounted display may implement virtual reality (VR) or augmented reality (AR). The virtual reality (VR) has an advantage of allowing even an image of 1-inch size to be viewed in 60-inch size because of excellent user immersion. To this end, the head mounted display is applied with a small display device having ultra-high resolution.

The description provided in the description of the related art section should not be assumed to be prior art merely because it is mentioned in or associated with the description of the related art section. The description of the related art section may include information that describes one or more aspects of the subject technology, and the description in this section does not limit the disclosure.

### BRIEF SUMMARY

In a case of a small display device with an ultra-high resolution, it is difficult to implement a light-emissive layer using a fine metal mask because of a narrow pixel spacing.

In addition, to implement the small display device with the ultra-high resolution, a semiconductor process using expensive equipment is required.

Accordingly, various embodiments of a display device are provided that are capable of constructing dense pixels to realize ultra-high resolution without using the expensive equipment, as confirmed through various experiments.

An embodiment of the present disclosure is to provide a display device capable of simplifying the process and avoiding the use of expensive equipment by omitting a color filter. Accordingly, a purpose is to prevent problems that may arise as the number of process steps increases.

In addition, an embodiment of the present disclosure is to provide a display device capable of improving light efficiency of a light-emissive element by including a light-emissive layer that emits white light.

To elaborate, the display device described achieves color generation without using traditional color filters by utilizing a micro cavity structure. This structure controls the optical distance between a white light emitting layer and a multi-layer reflective electrode in each sub-pixel. Each reflective electrode includes a lower reflective layer, a wavelength selective layer, and an upper reflective layer, with varying thicknesses that enable the selective emission of red, green, and blue light. By adjusting these layer properties, unwanted spectral components are suppressed, resulting in improved color purity, higher optical efficiency, and reduced light loss.

The device architecture supports high resolution by employing complementary metal oxide semiconductor processes and compact pixel layouts, making it suitable for applications such as head mounted displays. Eliminating the need for color filters simplifies the manufacturing process, reduces production costs, and enhances energy efficiency, while also providing improved image quality and color accuracy for a more immersive visual experience.

Technical benefits according to the present disclosure are not limited to the above-mentioned benefits. Other benefits and advantages according to the present disclosure that are not mentioned may be understood based on following descriptions, and may be more clearly understood based on embodiments according to the present disclosure. Further, it will be easily understood that the benefits and advantages according to the present disclosure may be realized using means shown in the claims or combinations thereof.

A display device according to an embodiment of the present disclosure includes a first substrate including a plurality of sub-pixels areas corresponding to a plurality of sub-pixels, each first electrode disposed on the substrate and in each of the sub-pixels, a light-emissive layer disposed on the first electrode, a second electrode disposed on the light-emissive layer, and each reflective electrode disposed on the substrate and in each of the sub-pixels, and the reflective electrodes have different thicknesses in the respective sub-pixels.

A display device according to an embodiment of the present disclosure includes a display device including a first substrate including first to third sub-pixels that emit light of different colors, respectively, each first electrode disposed in each of the first to third sub-pixels, a light-emissive layer disposed on the first electrode, a second electrode disposed on the light-emissive layer, and first to third reflective electrodes respectively disposed in the first to third sub-pixels, each of the first to third reflective electrodes includes a lower reflective layer, a wavelength selective layer, and an upper reflective layer, the lower reflective layer and the upper reflective layer have different thicknesses, and the second electrode and the first reflective electrode are disposed to be spaced apart from each other by a first distance in the first sub-pixel, the second electrode and the second reflective electrode are disposed to be spaced apart from each other by a second distance different from the first distance in the second sub-pixel, and the second electrode and the third reflective electrode are disposed to be spaced apart from each other by a third distance different from the first distance and the second distance in the third sub-pixel.

According to the embodiment of the present disclosure, by omitting the color filter that requires the expensive equipment in the small display device with the ultra-high resolution, the cost of the final product may be reduced.

In addition, by omitting the color filter, the process steps may be simplified, and thus the process optimization may be implemented. Accordingly, production energy may be reduced.

In addition, because the color filter may be omitted, light may be prevented from being lost while passing through the color filter, thereby improving the light efficiency.

According to the embodiment of the present disclosure, the reflective electrode having the multi-layer structure including the lower reflective layer, the wavelength selective layer, and the upper reflective layer may be disposed in each sub-pixel to selectively emit light in the specific wavelength range.

In addition, light in the range other than the target wavelength range may be absorbed by adjusting the thickness of the upper reflective layer, and the wavelength range of light to be absorbed may be adjusted by adjusting the thickness of the wavelength selective layer to adjust the separation distance between the lower reflective layer and the upper reflective layer.

Accordingly, because light of the target color may be strongly emitted, the purity and the color reproduction rate of the color may be improved, and thus the user's immersion may be improved.

Effects of the present disclosure are not limited to the effects mentioned above, and other effects not mentioned will be clearly understood by those skilled in the art from the description as set forth below.

In addition to the above effects, specific effects of the present disclosure are described together while describing specific details for carrying out the present disclosure.

### BRIEF DESCRIPTION OF THE SEVERAL VIEWS OF THE DRAWINGS

FIG. 1 is a plan view of a display device according to an embodiment of the present disclosure.

FIG. 2 is a plan view illustrating a unit pixel according to an embodiment of the present disclosure.

FIG. 3 is a cross-sectional view taken along a line I-I′ in FIG. 1 according to an embodiment of the present disclosure.

FIGS. 4 to 6 are diagrams illustrating emission spectra for respective sub-pixels according to an embodiment of the present disclosure.

FIG. 7 is a cross-sectional view according to another embodiment of the present disclosure.

FIGS. 8 to 10 are enlarged views of reflective electrodes according to another embodiment of the present disclosure.

FIGS. 11 and 12 are graphs respectively showing light absorptivity and reflectivity based on a thickness of an upper reflective layer of a reflective electrode.

FIGS. 13 and 14 are graphs showing light absorptivity and reflectivity based on a thickness of a wavelength selective layer of a reflective electrode.

FIGS. 15 to 20 are graphs showing light reflectivity and absorptivity of respective sub-pixels according to another embodiment of the present disclosure.

FIGS. 21 to 23 are diagrams illustrating emission spectra of respective sub-pixels according to another embodiment of the present disclosure.

FIGS. 24 to 26 are a head mounted device including a display device according to an embodiment of the present disclosure.

### DETAILED DESCRIPTION

Advantages and features of the present disclosure, and a method of achieving the advantages and features will become apparent with reference to embodiments described below in detail together with the accompanying drawings. However, the present disclosure is not limited to the embodiments as disclosed under, but may be implemented in various different forms. Thus, these embodiments are set forth only to make the present disclosure complete, and to entirely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this disclosure, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify an entirety of the list of elements and may not modify the individual elements of the list.

In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when a first element or layer is referred to as being “connected to”, or “coupled to” a second element or layer, the first element may be directly connected to or coupled to the second element or layer, or one or more intervening elements or layers may be present therebetween.

To elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

In addition, it will also be understood that when an element or layer is referred to as being “between” two elements or layers, it may be the only element or layer between the two elements or layers, or one or more intervening elements or layers may also be present therebetween.

Further, as used herein, when a layer, film, area, plate, or the like is disposed “on” or “on a top” of another layer, film, area, plate, or the like, the former may directly contact the latter or still another layer, film, area, plate, or the like may be disposed between the former and the latter. As used herein, when a layer, film, area, plate, or the like is directly disposed “on” or “on a top” of another layer, film, area, plate, or the like, the former directly contacts the latter and still another layer, film, area, plate, or the like is not disposed between the former and the latter. Further, as used herein, when a layer, film, area, plate, or the like is disposed “below” or “under” another layer, film, area, plate, or the like, the former may directly contact the latter or still another layer, film, area, plate, or the like may be disposed between the former and the latter. As used herein, when a layer, film, area, plate, or the like is directly disposed “below” or “under” another layer, film, area, plate, or the like, the former directly contacts the latter and still another layer, film, area, plate, or the like is not disposed between the former and the latter.

It will be understood that the spatially relative terms can encompass different orientations of an element in use or operation in addition to the orientation depicted in the figures. For example, if an element in the figures is inverted, elements described as “below” or “beneath” other elements or features would then be oriented “over” the other elements or features. Thus, the example term “below” can encompass both an orientation of below and above. Similarly, the example term “above” or “over” can encompass both an orientation of “above” and “below”.

In descriptions of temporal relationships, for example, temporal precedent relationships between two events such as “after”, “subsequent to”, “before”, etc., another event may occur therebetween unless “directly after”, “directly subsequent” or “directly before” is not indicated. When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, areas, layers and/or periods, these elements, components, areas, layers and/or periods should not be limited by these terms. These terms are used to distinguish one element, component, area, layer or section from another element, component, area, layer or section. Thus, a first element, component, area, layer or section as described under could be termed a second element, component, area, layer or section, without departing from the spirit and scope of the present disclosure.

“At least one” should be understood as including a combination of one or more of the related components. For example, the term “at least one of first, second, and third components” includes not only the first, second, or third component, but also all combinations of two or more of the first, second, and third components.

A term “device” used herein may refer to a display device including a display panel and a driver for driving the display panel. Examples of the display device may include a light emitting element, and the like. In addition, examples of the device may include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including light emitting element and the like, but embodiments of the present disclosure are not limited thereto.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof. Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the aspects of the present disclosure, a source electrode and a drain electrode are distinguished from each other, for convenience of description. However, the source electrode and the drain electrode are used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

As used herein, “embodiments,” “examples,” “aspects, etc., should not be construed such that any aspect or design as described is superior to or advantageous over other aspects or designs. Further, the term ‘or’ means ‘inclusive or’ rather than ‘exclusive or’. That is, unless otherwise stated or clear from the context, the expression that ‘x uses a or b’ means one of natural inclusive permutations.

The terms used in the description as set forth below have been selected as being general and universal in the related technical field. However, there may be other terms than the terms depending on the development and/or change of technology, convention, preference of technicians, etc. Therefore, the terms used in the description as set forth below should not be understood as limiting technical ideas, but should be understood as examples of the terms for illustrating embodiments. Further, in a specific case, a term may be arbitrarily selected by the applicant, and in this case, the detailed meaning thereof will be described in a corresponding description period. Therefore, the terms used in the description as set forth below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase ‘immediately transferred’ or ‘directly transferred’ is used. Throughout the present disclosure, “A and/or B” means A, B, or A and B, unless otherwise specified, and “C to D” means C inclusive to D inclusive unless otherwise specified.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but may be interpreted as having a geometric relationship with each other in which the first direction, the second direction, and the third direction interest each other at an angle other than 90 degrees or the X-axis direction, the Y-axis direction, and the Z-axis direction are interest each other at an angle other than 90 degrees within a range in which a configuration of the present disclosure may work functionally.

A head mounted display implements an image in an enlarged manner at a close distance to user's eyes. Accordingly, to manufacture a small display device including the head mounted display, a technology of ultra-high resolution equal to or greater than 3000PPI is required. The small display device have a pixel size significantly smaller than a size of a pixel applied to a mobile phone or a large display device. For example, the pixel size of the mobile phone or the large display device is tens of μm to hundreds of μm, but the pixel size of the small display device is several μm. In addition, the small display device should have the ultra-high resolution while having the small pixel size to implement a clear image in front of the user's eyes.

In such a small display device to which the ultra-high resolution technology is applied, because sub-pixels are densely arranged, a transistor may be formed by applying a complementary metal oxide semiconductor (CMOS) process to realize a transistor having a smaller size than a thin film transistor (TFT).

In addition, in the small display device to which the ultra-high resolution technology is applied, because the sub-pixels are densely arranged, it is difficult to implement a light-emissive layer in a deposition method using a fine metal mask (FMM).

Accordingly, as one of methods for placing the light-emissive layer on the sub-pixels, a method for forming the light-emissive layer with an organic material that emits white light and extracting a different color from the white light for each sub-pixel via a color filter may be considered.

However, an expensive semiconductor exposure device is required to implement an ultra-high resolution image via the color filter, and the color filter needs to be formed at a low temperature, thereby complicating a process and increasing a cost of a final product.

In addition, when the color filter is used, light efficiency may decrease as an amount of light lost in the color filter increases.

Accordingly, an embodiment of the present disclosure may form a display device capable of emitting light of a different color for each sub-pixel without using the color filter by controlling light of a specific wavelength emitted by a micro cavity effect.

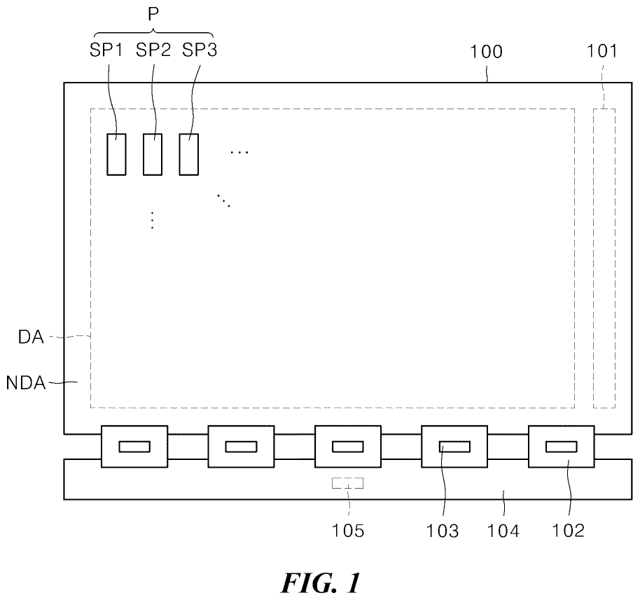

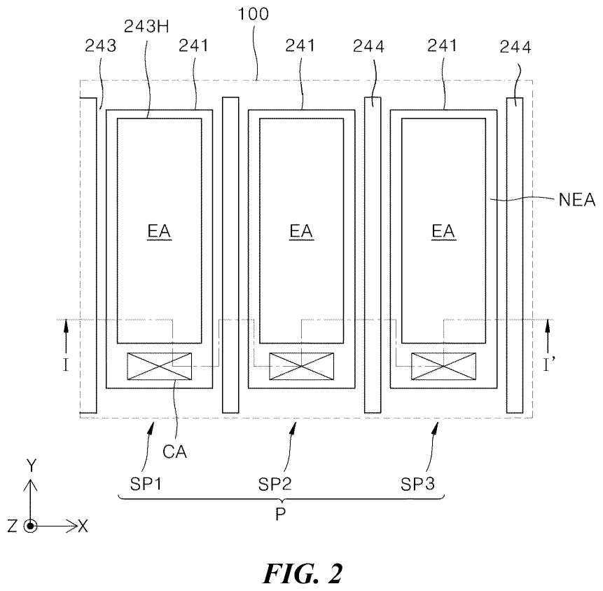

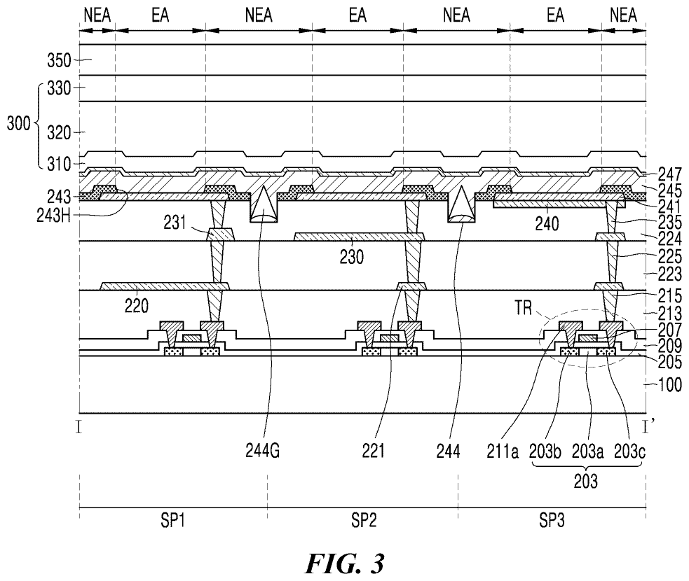

FIG. 1 is a plan view of a display device according to an embodiment of the present disclosure. FIG. 2 is a plan view illustrating a unit pixel according to an embodiment of the present disclosure. FIG. 3 is a cross-sectional view taken along a line I-I′ in FIG. 1 according to an embodiment of the present disclosure. FIG. 2 illustrates only three sub-pixels SP1, SP2, and SP3 for convenience of description.

Referring to FIGS. 1 to 3, the display device according to embodiments of the present disclosure may include a first substrate 100 including a display area DA and a non-display area NDA located outside the display area DA.

The display area DA may be an area in which an image is displayed. The non-display area NDA may be an area in which no image is displayed. The non-display area NDA may be located in a peripheral area (or an edge area) of the first substrate 100, but the present disclosure may not be limited thereto. For example, an area other than the light-emissive area EA in which light is emitted to the outside on the display area DA may be referred to as the non-display area DNA.

The non-display area NDA may be placed outside the display area DA. For example, the non-display area NDA may be an area adjacent to the display area DA. Further, the non-display area NDA may be an area disposed adjacent to the display area DA and configured to surround the display area DA. Various lines and circuits for driving the plurality of pixels of the display area DA may be disposed in the non-display area NDA. The non-display area NDA may also be referred to as a non-active area and include a pad area. For example, in the non-display area NDA, various lines and driving circuits may be mounted, and a pad portion to which an integrated circuit, a printed circuit, and the like are connected may be disposed, but the example embodiments of the present disclosure are not limited thereto.

A plurality of pixels P may be disposed in the display area DA. The image may be displayed in the display area DA via the plurality of pixels P. The pixel P may include a plurality of subpixels. Each of the plurality of subpixels is a minimum unit which configures the display area and n subpixels form one pixel. Each of the plurality of subpixels may emit light having different wavelengths from each other. The plurality of subpixels may include first to third subpixels which emit different color light from each other. For example, the sub-pixels may include red, green, and blue sub-pixels. Meanwhile, the sub-pixels may also include white sub-pixel. The plurality of subpixels may be variously modified in colors and configurations, as necessary. However, the present disclosure is not limited thereto.

For example, the plurality of subpixels may include red, green, and blue subpixels, in which the red, green, and blue subpixels may be disposed in a repeated manner. Alternatively, the plurality of subpixels may include red, green, blue, and white subpixels, in which the red, green, blue, and white subpixels may be disposed in a repeated manner, or the red, green, blue, and white subpixels may be disposed in a quad type. For example, the red sub pixel, the blue sub pixel, and the green sub pixel may be sequentially disposed along a row direction, or the red sub pixel, the blue sub pixel, the green sub pixel and the white sub pixel may be sequentially disposed along the row direction. However, in the embodiment of the present disclosure, the color type, disposition type, and disposition order of the subpixels are not limiting, and may be configured in various forms according to light-emitting characteristics, device lifespans, and device specifications.

Meanwhile, the subpixels may have different light-emitting areas according to light-emitting characteristics. For example, a subpixel that emits light of a color different from that of a blue subpixel may have a different light-emitting area from that of the blue subpixel. For example, the red subpixel, the blue subpixel, and the green subpixel, or the red subpixel, the blue subpixel, the white subpixel, and the green subpixel may each has a different light-emitting area.

A plurality of light-emitting elements may be disposed in each of the plurality of subpixels. The plurality of light-emitting elements may be configured differently depending on the type of display device. For example, when the display device is an inorganic light-emitting display device, the light-emitting element may be an inorganic light-emitting diode (LED), a micro light-emitting diode (micro LED), or a mini light-emitting diode (mini LED), but the example embodiments of the present disclosure are not limited thereto.

Various lines, circuits, and the like for operating the plurality of pixels P of a display area AA may be disposed in the non-display area NDA. For example, driving circuits including a gate driving circuit and a data driving circuit may be disposed in the non-display area NDA. Several drivers 101 for driving the display area AA may be disposed in the non-display area NDA. For example, the driver 101 may include a gate driver and a data driver, but the present disclosure may not be limited thereto.

The gate driver may be a circuit configured to drive a plurality of gate lines GL and can output gate signals to the plurality of gate lines GL.

The gate driver can receive various types of gate driving control signals GCS, and further, receive a first gate voltage corresponding to a turn-on level voltage and a second gate voltage corresponding to a turn-off level voltage. Thereby, the gate driver can generate gate signals and supply the generated gate signals to the plurality of gate lines GL.

In one or more aspects, the gate driver included in the display device may be embedded into the display panel by a gate-in-panel (GIP) technique. In an example where the gate driver is implemented by the gate-in-panel (GIP) technique, the gate driver may be disposed on the display panel during the manufacturing process of the display panel or display device.

The data driver may be a circuit for driving a plurality of data lines DL and can output data signals to the plurality of data lines DL.

The data driver can receive image data DATA in a digital form from a controller, and convert the received image data DATA into data signals in an analog form, and output the converted data signals to the plurality of data lines DL.

In some aspects, the data driver may be connected to the display panel by a tape-automated-bonding (TAB) technique, or connected to a conductive pad such as a bonding pad of the display panel by a chip-on-glass (COG) technique or a chip-on-panel (COP) technique, or connected to the display panel by a chip-on-film (COF) technique. However, aspects of the present disclosure are not limited thereto. In one or more aspects, the data driver may be disposed in, and/or electrically connected to, but not limited to, only one side or edge (e.g., an upper portion or a lower portion) of the display panel.

In one or more aspects, the data driver may be disposed in, and/or electrically connected to, but not limited to, two sides or edges (e.g., an upper portion and a lower portion) of the display panel or at least two of four sides or edges (e.g., the upper portion, the lower portion, a left portion, and a right portion) of the display panel according to driving schemes, panel design schemes, or the like.

A flexible printed circuit board 102 and a printed circuit board 104 may be disposed at an edge of at least one side of the non-display area NDA. For example, the flexible printed circuit board 102 may include a plurality of flexible printed circuit boards, but the present disclosure may not be limited thereto. An integrated circuit chip 103 may be disposed on the flexible circuit board 102. One side of the flexible circuit board 102 may be coupled to the first substrate 100, and the other side thereof may be coupled to the printed circuit board 104 and provide power and signals for driving a light-emissive element supplied from the printed circuit board 104 to the display area DA of the first substrate 100. For example, the signal for driving the light-emissive element may include a high potential voltage, a low potential voltage, a scan signal, a data signal, or the like.

The printed circuit board 104 may supply the signal to the integrated circuit chip 103 disposed on the flexible printed circuit board 102. Various components for supplying the various signals to the flexible printed circuit board 102 may be disposed on the printed circuit board 104. For example, the printed circuit board 104 may include a timing controller 105.

Each of the plurality of pixels P of the display area DA may be composed of the plurality of sub-pixels SP1, SP2, and SP3. The plurality of sub-pixels SP1, SP2, and SP3 may be arranged in an array on the display area AA. For example, the plurality of sub-pixels SP1, SP2, and SP3 may be spaced apart from each other in a first direction X and in a second direction Y intersecting the first direction X of the display area AA to form a matrix arrangement. The first direction may be an X-axis direction or a horizontal direction, and the second direction may be a Y-axis direction or a vertical direction. However, the present disclosure may not be limited thereto, and an arrangement order and an arrangement direction of the sub-pixels SP1, SP2, and SP3 may be variously changed.

Referring to FIGS. 2 and 3, the plurality of sub-pixels SP1, SP2, and SP3 may be disposed on the display area DA of the first substrate 100.

A plurality of light-emissive areas EA may be located to respectively correspond to the sub-pixels SP1, SP2, and SP3. A first light-emissive area EA may be located in a first sub-pixel SP1, a second light-emissive area EA may be located in a second sub-pixel SP2, and a third light-emissive area EA may be located in a third sub-pixel SP3.

The plurality of light-emissive areas EA are defined by a bank 243 including bank holes 243H. The bank hole 243H may be an opening exposing the light-emissive area EA. That is, areas exposed without being covered by the bank 243H may be the plurality of light-emissive areas EA.

A plurality of first electrodes 241 are disposed to respectively correspond to the plurality of sub-pixels SP1, SP2, and SP3. The plurality of first electrodes 241 may be disposed respectively in the sub-pixels SP1, SP2, and SP3 to be spaced apart from each other.

A portion of the first electrode 241 exposed by the bank hole 243H of the bank 243 may be defined as a light-emissive area EA. For example, a first light-emissive area EA may be defined by the bank hole 243H in the first sub-pixel SP1, a second light-emissive area EA may be defined by the bank hole 243H in the second sub-pixel SP2, and a third light-emissive area EA may be defined by the bank hole 243H in the third sub-pixel SP3.

Trenches 244 extending in the second direction Y may be defined in boundary areas between the plurality of sub-pixels SP1, SP2, and SP3. The trenches 244 may be disposed between the first sub-pixel SP1 and the second sub-pixel SP2, between the second sub-pixel SP2 and the third sub-pixel SP3, and between the third sub-pixel SP3 and the first sub-pixel SP1 adjacent to each other. For example, the trench 244 may have a length greater than a length of the plurality of light-emissive areas EA.

The first electrode 241 of each of the plurality of sub-pixels SP1, SP2, and SP3 may be connected to at least one transistor disposed on the first substrate 100 via each contact area CA. Hereinafter, a description will be made with reference to FIG. 3.

The display device according to an embodiment of the present disclosure may be of one of a top emission type and a bottom emission type, depending on a direction in which light emitted from a light-emissive layer is emitted. Hereinafter, a description will be made using the top emission type as an example.

Referring to FIG. 3, the transistor may be disposed on the first substrate 100. Each transistor may be implemented as a thin film transistor (TFT). The first substrate 100 may include a silicon wafer. In an embodiment, the first substrate 100 may include glass or plastic.

On the first substrate 100, a driving circuit including various signal lines, transistors, a capacitor, and the like may be disposed for each of the sub-pixels SP1, SP2, and SP3. The signal lines may include a gate line, a data line, a power line, and a reference line, and the transistors may include a switching transistor and a driving transistor. For example, the switching transistor and the driving transistor may be formed on the first substrate 100 using a complementary metal oxide semiconductor (CMOS) process. In an embodiment of the present disclosure, only a driving transistor TR is illustrated for convenience of description.

The switching transistor is switched in response to a gate signal supplied to the gate line and supplies a data voltage supplied from the data line to the driving transistor, and selects the sub-pixels SP1, SP2, and SP3. The driving transistor TR serves to drive the light-emissive element by supplying power to the first electrode 241 of the sub-pixel SP1, SP2, and SP3 selected from the switching transistor.

The capacitor serves to maintain the data voltage supplied to the driving transistor for one frame. Electrodes of the capacitor may be electrically connected to the driving transistor.

The driving transistor TR may include a semiconductor layer 203, a gate insulating layer 205, a gate electrode 207, and source/drain electrodes 211a and 211b. The gate insulating layer 205 may be disposed between the semiconductor layer 203 and the gate electrode 207. An insulating layer that reduces or prevents penetration of moisture or impurities may be further included between the substrate 100 and the semiconductor layer 203.

The semiconductor layer 203 may be made of an oxide semiconductor or silicon-based semiconductor material. For example, the semiconductor layer 203 may include a transparent oxide semiconductor material such as Indium-gallium-zinc-oxide (IGZO) or Indium-zinc-oxide (IZO). In addition, the semiconductor layer 203 may include a polysilicon semiconductor material.

The semiconductor layer 203 may include a channel area 203a, a source area 203b, and a drain area 203c. The gate insulating layer 205 may be composed of a single layer or a plurality of layers of silicon oxide (SiOx) or silicon nitride (Sinx).

The gate electrode 207 may be disposed on the gate insulating layer 205. An area of the semiconductor layer 203 overlapping the gate electrode 207 in a vertical direction may be the channel area 203a. The source area 203b and the drain area 203c may be located on both sides of the channel area 203a.

An interlayer insulating layer 209 may be disposed on the gate electrode 207. A source electrode 211a and a drain electrode 211b may be disposed to extend through the interlayer insulating layer 209 and the gate insulating layer 205. The source electrode 211a and the drain electrode 211b may be disposed on both sides with the gate electrode 207 interposed therebetween, and may be connected to the source area 203b and the drain area 203c of the semiconductor layer 203, respectively.

A first insulating layer 213 may be disposed on the interlayer insulating layer 209, the source electrode 211a, and the drain electrode 211b. The first insulating layer 213 may include an inorganic insulating material or an organic insulating material. The first insulating layer 213 may cover the transistors including the driving transistors TR, the various signal lines, the capacitor, and the like disposed on the first substrate 100.

A first reflective electrode 220 and a plurality of first contact electrodes 221 may be disposed on the first insulating layer 213. The first reflective electrode 220 may be disposed in the first sub-pixel SP1, and the plurality of first contact electrodes 221 may be disposed in the second sub-pixel SP2 and the third sub-pixel SP3, respectively. The first reflective electrode 220 and the plurality of first contact electrodes 221 may be disposed on the same plane.

A plurality of first vias 215 extending through the first insulating layer 213 may be disposed to be spaced apart from each other. Respective one surfaces of the plurality of first vias 215 may be respectively connected to the first reflective electrode 220 and the plurality of first contact electrodes 221, and the other surfaces thereof opposite to the respective one surfaces may be electrically connected to the driving transistors. For example, the plurality of first contact electrodes 221 may be connected to the drain electrodes 211b of the driving transistors TR.

In an embodiment, in the first sub-pixel SP1, a first reflective electrode 220 and the first via 215 may be integrally formed. In the second sub-pixel SP2, the first contact electrode 221 and the first via 215 may be integrally formed. In the third sub-pixel SP3, the first contact electrode 221 and the first via 215 may be integrally formed.

The first reflective electrode 220 and the first contact electrodes 221 may be made of a metal material having high reflectivity, such as silver (Ag), a silver alloy, aluminum (Al), or an aluminum alloy. The first via 215 may include a metal material.

A second insulating layer 223 may be disposed on the first insulating layer 213, the first reflective electrode 220, and the plurality of first contact electrodes 221. The second insulating layer 223 may include an inorganic insulating material or an organic insulating material.

A second reflective electrode 230 and a plurality of second contact electrodes 231 may be disposed on the second insulating layer 223. The second reflective electrode 230 may be disposed in the second sub-pixel SP2, and the plurality of second contact electrodes 231 may be disposed in the first sub-pixel SP1 and the third sub-pixel SP3, respectively. The second reflective electrode 230 and the plurality of second contact electrodes 231 may be disposed on the same plane.

A plurality of second vias 225 extending through the second insulating layer 223 may be disposed to be spaced apart from each other. Respective one surfaces of the plurality of second vias 225 may be respectively connected to the second reflective electrode 230 and the plurality of second contact electrodes 231, and the other surfaces thereof opposite to the respective one surfaces may be respectively electrically connected to the first reflective electrode 220 and the plurality of first contact electrodes 221.

In an embodiment, in the second sub-pixel SP2, the second reflective electrode 230 and the second via 225 may be integrally formed. In the first sub-pixel SP2, the second contact electrode 231 and the second via 225 may be integrally formed. In the third sub-pixel SP3, the third contact electrode 231 and the second via 225 may be integrally formed.

The second reflective electrode 230 and the second contact electrodes 231 may be made of a metal material having high reflectivity, such as silver (Ag), a silver alloy, aluminum (Al), or an aluminum alloy. The second via 225 may include a metal material.

A third insulating layer 224 may be disposed on the second reflective electrode 230 and the second contact electrode 231. The third insulating layer 224 may include an organic insulating material. The third insulating layer 224 serves to planarize a step generated by the lower circuit elements including the driving transistor TR. The third insulating layer 224 may also be referred to as a planarization layer.

The plurality of first electrodes 241 may be disposed on the third insulating layer 224 respectively in the sub-pixels SP1, SP2, and SP3.

In the third sub-pixel SP3, a third reflective electrode 240 may be disposed in contact with a rear surface of the first electrode 241, but the preset disclosure may not be limited thereto. For example, an insulating layer may be further disposed on the third reflective electrode 240, and the plurality of first electrodes 241 may be disposed on the insulating layer. In this case, the third reflective electrode 240 and the first electrode 241 may be electrically connected to each other via an additional via electrode.

A plurality of third vias 235 extending through the third insulating layer 224 may be disposed to be spaced apart from each other. Respective one surfaces of the plurality of third vias 235 may be respectively connected to the respective first electrodes 241 of the sub-pixels SP1, SP2, and

SP3, and the other surfaces thereof opposite to the respective one surfaces may be respectively electrically connected to the second reflective electrode 230 and the plurality of second contact electrodes 231. In the third sub-pixel SP3, the third reflective electrode 240 may be connected to the second contact electrode 231 via the third via 235, but the preset disclosure may not be limited thereto.

The third reflective electrode 240 may be made of a metal material having high reflectivity, such as silver (Ag), a silver alloy, aluminum (Al), or an aluminum alloy. The third via 235 may include a metal material.

The first electrode 241 disposed in each of the sub-pixels SP1, SP2, and SP3 may include a transparent metal oxide such as indium tin oxide (ITO) or indium zinc oxide (IZO). Alternatively, the first electrode 241 may have a single-layer or multi-layer structure including a reflective metal film made of silver (Ag), aluminum (Al), gold (Au), nickel (Ni), chromium (Cr), or a compound thereof. The first electrode 241 may also be referred to as a pixel electrode or an anode electrode.

The bank 243 may be disposed on the third insulating layer 224. The bank 243 serves to distinguish the sub-pixels SP1, SP2, and SP3 from each other. To this end, the bank 243 may be formed to cover an edge of the first electrode 241. In addition, the light-emissive area EA and the non-light-emissive area NEA may be distinguished from each other via the bank hole 243H of the bank 243. The bank 243 may prevent light of the different colors from being mixed with each other and output between the adjacent sub-pixels. The bank 243 may include an organic insulating layer made of polyimide or epoxy. In an example, the bank 243 may include one of a black resin, graphite, and black ink. In the example where the bank 243 includes a material including a black pigment or a black dye, the luminance of the display device can be further improved because light from the outside or light reflected from the outside can be blocked.

The trench 244 may be disposed in the bank 243 and the third insulating layer 224. The trench 244 may have a concave shape including a bottom surface and both side surfaces extending from the bottom surface. The trench 244 may extend through the bank 243 in the boundary area between the adjacent sub-pixels SP1, SP2, and SP3, and may extend in a thickness direction of the third insulating layer 224. For example, the trench 244 may be disposed in a boundary area between the first sub-pixel SP1 and the second sub-pixel SP2. For example, the trench 244 may be disposed in a boundary area between the second sub-pixel SP2 and the third sub-pixel SP3. The trench 244 may be disposed in the non-light-emissive area NEA. In another example, the trench 244 may extend toward the second insulating layer 223.

A light-emissive layer 245 may be disposed on the first electrode 241. In an example, the light-emissive layer 245 may include an organic material that emits white light.

The light-emissive layer 245 may include a multi-stack structure in which at least two stacks including a hole transport layer HTL, a light-emissive material layer EML and an electron transport layer ETL, a hole blocking layer HBL, a hole injecting layer HIL, an electron blocking layer EBL, and an electron injecting layer EIL are stacked.

The light-emissive layer 245 may be disposed on an entire surface of the display area DA. Accordingly, as the light-emissive layer 245 is disposed on the bottom surface of the trench 244 and an upper edge of the trench 244, and an air gap 244G may be formed in the trench 244. At least a portion of the light-emissive layer 245 disposed in the trench 244 may be disconnected. For example, a portion of the light-emissive layer 245 disposed on the bottom surface of the trench 244 and a portion of the light-emissive layer 245 disposed on the side surface close to the bottom surface may not be connected to each other. Accordingly, a leakage current may be prevented from occurring between the adjacent sub-pixels SP1, SP2, and SP3.

The second electrode 247 may be disposed on the light-emissive layer 245. The second electrode 247 may be a common layer commonly formed in the plurality of sub-pixels SP1, SP2, and SP3. The second electrode 247 may also be referred to as a common electrode or a cathode electrode. The second electrode 247 may include a semi-transmissive metal material. For example, the second electrode 247 may include magnesium (Mg), silver (Ag), or an alloy of magnesium (Mg) and silver (Ag).

The light-emissive element may be formed to include the first electrode 241, the light-emissive layer 245, and the second electrode 247.

Each of the first reflective electrode 220, the second reflective electrode 230, and the third reflective electrode 240 may be disposed to overlap the second electrode 247 in the vertical directions. Accordingly, a micro cavity effect may be obtained between the second electrode 247 and the first reflective electrode 220, between the second electrode 247 and the second reflective electrode 230, and between the second electrode 247 and the third reflective electrode 240.

The micro cavity effect is a phenomenon in which an emission spectrum changes. For example, the emission spectrum may be changed by an interference effect of light occurring by reflectivity of the reflective electrode and transmittance of the second electrode, and a distance between the reflective electrode and the second electrode. When the micro cavity effect is used, light of a specific wavelength may be selectively emitted.

For example, in the first sub-pixel SP1, the first reflective electrode 220 and the second electrode 247 are spaced apart from each other by a first distance, and in the second sub-pixel SP2, the second reflective electrode 230 and the second electrode 247 are spaced apart from each other by a second distance. In addition, in the third sub-pixel SP3, the third reflective electrode 240 and the second electrode 247 are spaced apart from each other by a third distance. In addition, the first distance, the second distance, and the third distance may be different from each other. Accordingly, light of the different colors may be emitted from the sub-pixels SP1, SP2, and SP3. For example, red light may be emitted from the first sub-pixel SP1, green light may be emitted from the second sub-pixel SP2, and blue light may be emitted from the third sub-pixel SP3.

An encapsulating area 300 may be disposed on the second electrode 247. The encapsulating area 300 may seal the driving transistor TR and the light-emissive element thereunder. The encapsulating area 300 may prevent the moisture or the foreign substances from penetrating from the outside. The encapsulating area 300 may include a multi-layer structure including an inorganic insulating material and an organic insulating material. For example, the encapsulating area 300 may include a first encapsulating layer 310, a second encapsulating layer 320, and a third encapsulating layer 330.

The first encapsulating layer 310 and the third encapsulating layer 330 may include an inorganic insulating material. For example, the material may be selected from aluminum oxide (AlxOy), silicon oxide (SiOx), silicon nitride (SiNx), silicon oxynitride (SiON), and the like.

A second substrate 350 may be disposed on the encapsulating area 300. The second substrate 350 may be referred to as a cover window, a window cover, or a cover glass. The second substrate 350 may include a glass substrate, but the present disclosure may not be limited thereto. The second substrate 350 may include a plastic film. In addition, the second substrate 350 may be omitted.

The display device according to an embodiment of the present disclosure may control emitted light of the specific wavelength via the micro cavity effect, thereby emitting light of the different color for each sub-pixel without using a color filter. For example, the first sub-pixel SP1 may emit red light, the second sub-pixel SP2 may emit green light, and the third sub-pixel SP3 may emit blue light.

Because the display device according to an embodiment of the present disclosure does not use the color filter, the third encapsulating layer 330 and the second substrate 350 may be disposed in contact with each other.

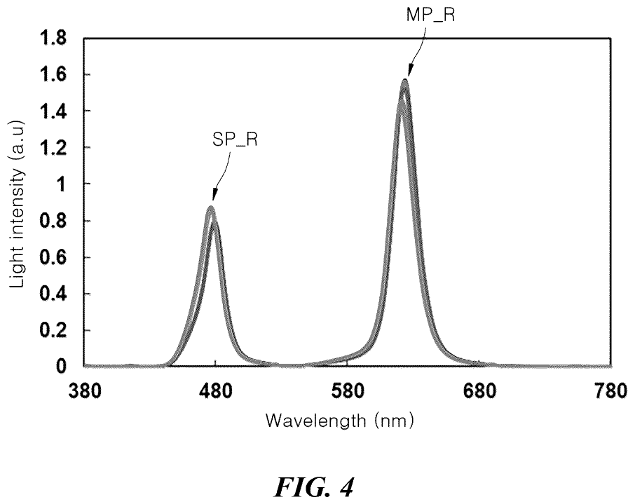

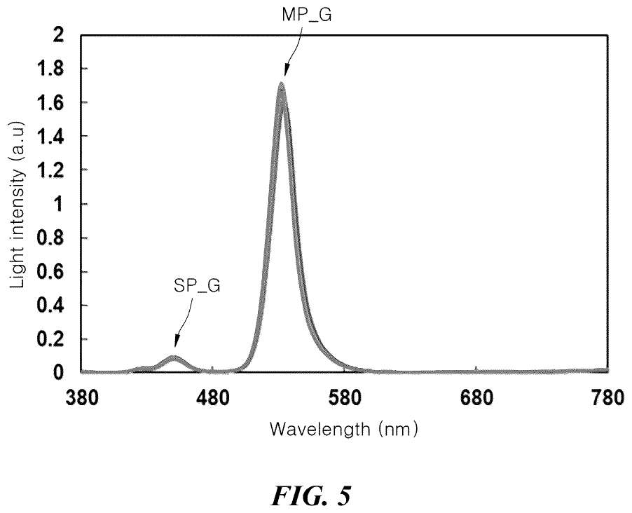

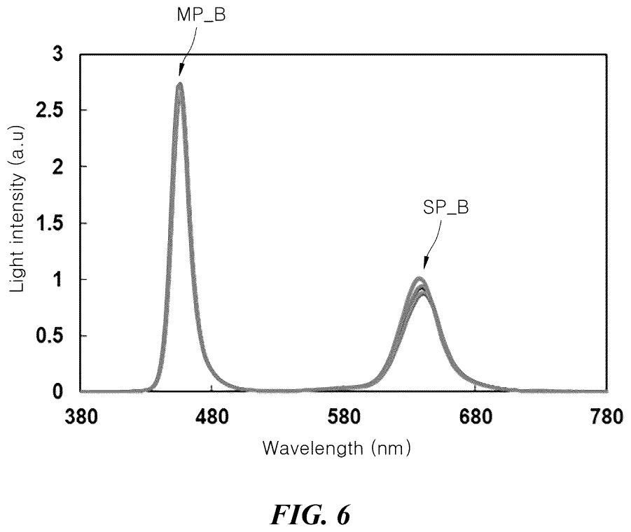

FIGS. 4 to 6 are diagrams illustrating emission spectra for respective sub-pixels according to an embodiment of the present disclosure. FIG. 4 illustrates an emission spectrum of a first sub-pixel. FIG. 5 illustrates an emission spectrum of a second sub-pixel. FIG. 6 illustrates an emission spectrum of a third sub-pixel. In FIGS. 4 to 6, a horizontal axis represents a wavelength (nm) of light, and a vertical axis represents intensity of light. The intensity of light is a relative value based on a maximum value of the emission spectrum.

Referring to FIG. 4, it may be seen that light emitted from the first sub-pixel has a main emission peak MP_R at a wavelength in a range of 600 nm to 670 nm, and also has a sub-emission peak SP_R at a wavelength in a range of 450 nm to 500 nm. Accordingly, red light may be emitted in the first sub-pixel.

Referring to FIG. 5, it may be seen that light emitted from the second sub-pixel has a main emission peak MP_G at a wavelength in a range of 495 nm to 570 nm, and also has a sub-emission peak SP_G at a wavelength in a range of 450 nm to 470 nm. Accordingly, green light may be emitted in the second sub-pixel.

Referring to FIG. 6, it may be seen that light emitted from the third sub-pixel has a main emission peak MP_B at a wavelength in a range of 400 nm to 495 nm, and also has a sub-emission peak SP_B at a wavelength in a range of 590 nm to 680 nm. Accordingly, blue light may be emitted in the third sub-pixel.

Referring to FIGS. 4 to 6, the sub-emission peaks SP_R, SP_G, and SP_B appearing in areas other than those of the main emission peaks MP_R, MP_G, and MP_B in the respective first to third sub-pixels SP1 to SP3 may be noise peaks. The noise peaks may reduce purity of the colors of light emitted at the main emission peaks MP_R, MP_G, and MP_B. Accordingly, when the noise peaks are removed, the purity of the colors of light emitted at the main emission peaks MP_R, MP_G, and MP_B may be improved. When the purity of the color is improved, a color reproduction rate may be improved, and the color may be expressed uniformly because there is little effect on a luminance change.

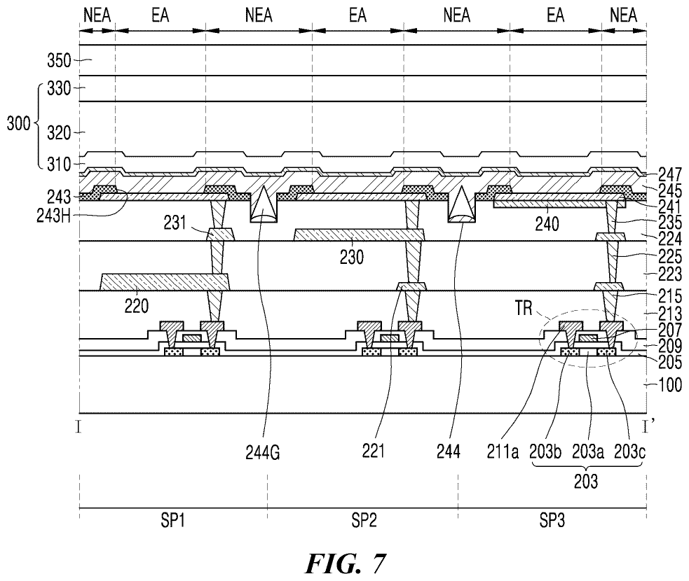

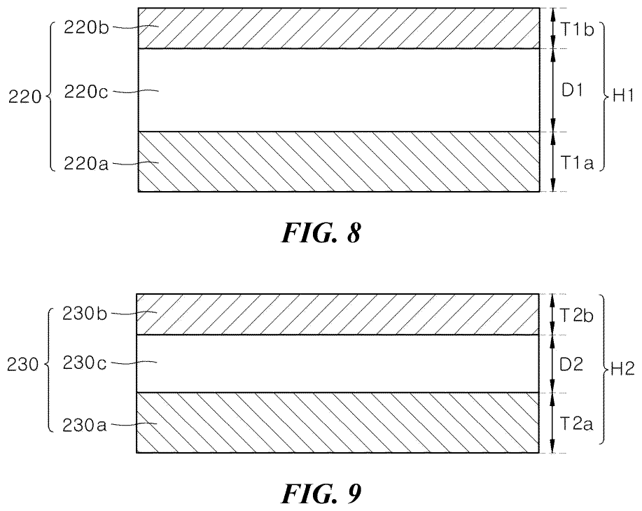

FIG. 7 is a cross-sectional view according to another embodiment of the present disclosure. Further, FIGS. 8 to 10 are enlarged views of reflective electrodes according to another embodiment of the present disclosure. In FIGS. 7 to 10, the same reference numerals will be assigned to the same components as the components described in FIG. 3, and a description thereof will be made briefly or omitted.

Referring to FIG. 7, the first insulating layer 213 may be disposed in the sub-pixels SP1, SP2, and SP3 where the driving transistors TR are respectively disposed. The first insulating layer 213 may include an inorganic insulating material or an organic insulating material. For example, the first insulating layer 213 may include at least one of silicone oxide (SiOx), silicone nitride (SiNx), and silicone oxynitride (SiOxNy), alternatively, the first insulating layer 213 may be formed of an organic layer such as an acryl-based material, an epoxy-based material, a phenolic-based material, a polyamide-based material, or a polyimide-based material, but example embodiments of the present disclosure are not limited thereto.

The first reflective electrode 220 and the plurality of first contact electrodes 221 may be disposed on the first insulating layer 213. The first reflective electrode 220 may be disposed in the first sub-pixel SP1, and the plurality of first contact electrodes 221 may be disposed in the second sub-pixel SP2 and the third sub-pixel SP3, respectively. The first reflective electrode 220 and the plurality of first contact electrodes 221 may be disposed on the same plane.

Each of the first reflective electrode 220 and the plurality of first contact electrodes 221 may be connected to the driving transistor TR via the first via 215.

Referring to FIGS. 7 and 8 together, the first reflective electrode 220 may be composed of multiple layers. For example, the first reflective electrode 220 may include a first lower reflective layer 220a, a first wavelength selective layer 220c, and a first upper reflective layer 220b. The first lower reflective layer 220a and the first upper reflective layer 220b may be disposed to be spaced apart from each other. For example, the first lower reflective layer 220a may be disposed on one surface of the first wavelength selective layer 220c, and the first upper reflective layer 220b may be disposed on the other surface opposite to the one surface of the first wavelength selective layer 220c. Accordingly, the first wavelength selective layer 220c may be disposed between the first lower reflective layer 220a and the first upper reflective layer 220b.

The first lower reflective layer 220a, the first upper reflective layer 220b, and the first contact electrodes 221 may be made of a metal material having high reflectance, such as silver (Ag), a silver alloy, aluminum (Al), or an aluminum alloy. The first via 215 may include a metal material.

The first wavelength selective layer 220c may include an inorganic insulating material, an organic insulating material, a polymer, a monomer, or the like. For example, the first wavelength selective layer 220c may include silicon oxide (SiOx), silicon nitride (SiNx), or polyimide.

The first lower reflective layer 220a and the first upper reflective layer 220b may have different thicknesses. For example, the first lower reflective layer 220a may have a first thickness T1a, and the first upper reflective layer 220b may have a second thickness T1b. In this case, the second thickness T1b may be smaller than the first thickness T1a. For example, the first thickness T1a of the first lower reflective layer 220a may be a thickness of 50 nm to 200 nm. The second thickness T1b of the first upper reflective layer 220b may be a thickness of 5 nm to 45 nm.

The first wavelength selective layer 220c may have a thickness such that the first lower reflective layer 220a and the first upper reflective layer 220b may be spaced apart from each other by a first distance D1. For example, in the first sub-pixel SP1, the first lower reflective layer 220a and the first upper reflective layer 220b may be spaced apart from each other by the first distance D1 of 390 nm to 410 nm by the first wavelength selective layer 220c.

Accordingly, the first reflective electrode 220 including the first lower reflective layer 220a, the first wavelength selective layer 220c, and the first upper reflective layer 220b may have a first height H1.

The second insulating layer 223 may be disposed on the first insulating layer 213, the first reflective electrode 220, and the plurality of first contact electrodes 221. The second insulating layer 223 may include an inorganic insulating material or an organic insulating material. For example, the second insulating layer 223 may include at least one of silicone oxide (SiOx), silicone nitride (SiNx), and silicone oxynitride (SiOxNy), alternatively, the second insulating layer 223 may be formed of an organic layer such as an acryl-based material, an epoxy-based material, a phenolic-based material, a polyamide-based material, or a polyimide-based material, but example embodiments of the present disclosure are not limited thereto.

The second reflective electrode 230 and the plurality of second contact electrodes 231 may be disposed on the second insulating layer 223. The second reflective electrode 230 may be disposed in the second sub-pixel SP2, and the plurality of second contact electrodes 231 may be disposed in the first sub-pixel SP1 and the third sub-pixel SP3, respectively. The second reflective electrode 230 and the plurality of second contact electrodes 231 may be disposed on the same plane.

The second reflective electrode 230 and the plurality of second contact electrodes 231 may be connected to the first contact electrodes 221 and the first reflective electrode 220 via the second vias 225, respectively. The second vias 225 may pass through the first reflective electrode 220 and the plurality of first contact electrodes 221 to be electrically connected to the first vias 215, respectively.

Referring to FIGS. 7 and 9 together, the second reflective electrode 230 may be composed of multiple layers. For example, the second reflective electrode 230 may include a second lower reflective layer 230a, a second wavelength selective layer 230c, and a second upper reflective layer 230b. The second lower reflective layer 230a and the second upper reflective layer 230b may be disposed to be spaced apart from each other. For example, the second lower reflective layer 230a may be disposed on one surface of the second wavelength selective layer 230c, and the second upper reflective layer 230b may be disposed on the other surface opposite to the one surface of the second wavelength selective layer 230c. Accordingly, the second wavelength selective layer 230c may be disposed between the second lower reflective layer 230a and the second upper reflective layer 230b.

The second lower reflective layer 230a, the second upper reflective layer 230b, and the second contact electrodes 231 may be made of a metal material having high reflectance, such as silver (Ag), a silver alloy, aluminum (Al), or an aluminum alloy. The second via 225 may include a metal material.

The second wavelength selective layer 230c may include an inorganic insulating material, an organic insulating material, a polymer, a monomer, or the like. For example, the second wavelength selective layer 230c may include silicon oxide (SiOx), silicon nitride (SiNx), or polyimide.

The second lower reflective layer 230a and the second upper reflective layer 230b may have different thicknesses. For example, the second lower reflective layer 230a may have a first thickness T2a, and the second upper reflective layer 230b may have a second thickness T2b. In this case, the second thickness T2b may be smaller than the first thickness T2a. For example, the first thickness T2a of the second lower reflective layer 230a may be a thickness of 50 nm to 200 nm. The second thickness T2b of the second upper reflective layer 230b may be a thickness of 5 nm to 45 nm.

The second wavelength selective layer 230c may have a thickness such that the second lower reflective layer 230a and the second upper reflective layer 230b may be spaced apart from each other by a second distance D2. For example, in the second sub-pixel SP2, the second lower reflective layer 230a and the second upper reflective layer 230b may be spaced apart from each other by the second distance D2 of 280 nm to 300 nm by the second wavelength selective layer 230c.

Accordingly, the second reflective electrode 230 including the second lower reflective layer 230a, the second wavelength selective layer 230c, and the second upper reflective layer 230b may have a second height H2.

A third insulating layer 224 may be disposed on the second insulating layer 223, the second reflective electrode 230, and the plurality of second contact electrodes 231. The third insulating layer 224 may include an organic insulating material. For example, the third insulating layer 224 may be formed of an organic layer such as an acryl-based material, an epoxy-based material, a phenolic-based material, a polyamide-based material, or a polyimide-based material, but example embodiments of the present disclosure are not limited thereto.

The third reflective electrode 240 may be disposed on the third insulating layer 224. The third reflective electrode 240 may be disposed in the third sub-pixel SP3.

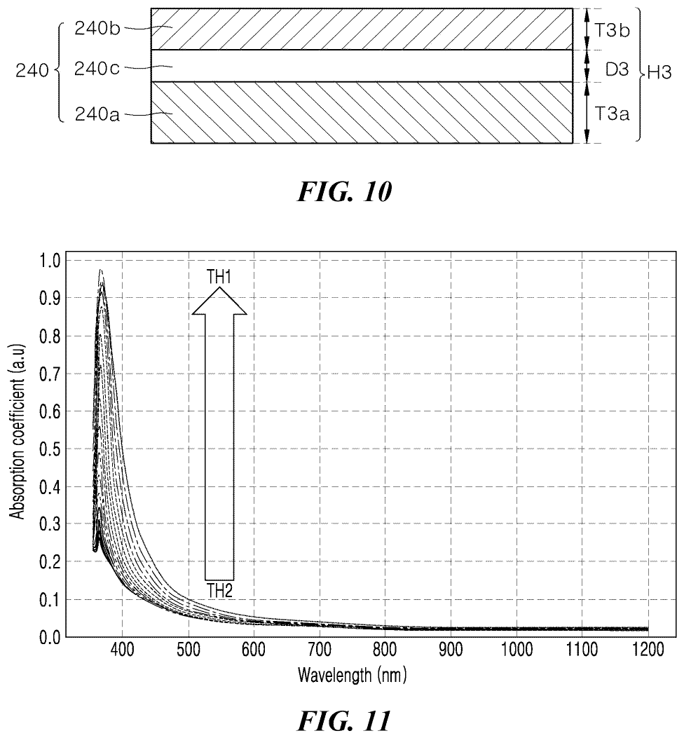

Referring to FIGS. 7 and 10 together, the third reflective electrode 240 may be composed of multiple layers. For example, the third reflective electrode 240 may include a third lower reflective layer 240a, a third wavelength selective layer 240c, and a third upper reflective layer 240b. The third lower reflective layer 240a and the third upper reflective layer 240b may be disposed to be spaced apart from each other. For example, the third lower reflective layer 240a may be disposed on one surface of the third wavelength selective layer 240c, and the third upper reflective layer 240b may be disposed on the other surface opposite to the one surface of the third wavelength selective layer 240c. Accordingly, the third wavelength selective layer 240c may be disposed between the third lower reflective layer 240a and the third upper reflective layer 240b.

The third reflective electrode 240 may be made of a metal material having high reflectivity, such as silver (Ag), a silver alloy, aluminum (Al), or an aluminum alloy.

The third wavelength selective layer 240c may include an inorganic insulating material, an organic insulating material, a polymer, a monomer, or the like. For example, the third wavelength selective layer 240c may include silicon oxide (SiOx), silicon nitride (SiNx), or polyimide.

The third lower reflective layer 240a and the third upper reflective layer 240b may have different thicknesses. For example, the third lower reflective layer 240a may have a first thickness T3a, and the third upper reflective layer 240b may have a second thickness T3b. In this case, the second thickness T3b may be smaller than the first thickness T3a. For example, the first thickness T3a of the third lower reflective layer 240 a may be a thickness of 50 nm to 200 nm. The second thickness T3b of the third upper reflective layer 240b may be a thickness of 5 nm to 45 nm.

The third wavelength selective layer 240c may have a thickness such that the third lower reflective layer 240a and the third upper reflective layer 240b may be spaced apart from each other by a third distance D3. For example, in the third sub-pixel SP3, the third lower reflective layer 240a and the third upper reflective layer 240b may be disposed to be spaced apart from each other by the third distance D3 of 110 nm to 130 nm by the third wavelength selective layer 240c.

Accordingly, the third reflective electrode 240 including the third lower reflective layer 240a, the third wavelength selective layer 240c, and the third upper reflective layer 240b may have a third height H3.

The first reflective electrode 220, the second reflective electrode 230, and the third reflective electrode 240 respectively disposed in the sub-pixels SP1, SP2, and SP3 may have different heights because the upper and lower reflective layers of the reflective electrodes are disposed to be spaced apart from each other by the first to third distances D1, D2, and D3 as a result of the first wavelength selective layer 220c, the second wavelength selective layer 230c, and the third wavelength selective layer 240c, respectively.

For example, among the first distance D1, the second distance D2, and the third distance D3, a value of the first distance D1 is the greatest, and a value of the third distance D3 is the smallest. Accordingly, the first height H1 of the first reflective electrode 220 disposed in the first sub-pixel SP1 is the greatest, and the third height H3 of the third reflective electrode 240 disposed in the third sub-pixel SP3 is the smallest.

Because the first reflective electrode 220, the second reflective electrode 230, and the third reflective electrode 240 respectively disposed in the sub-pixels SP1, SP2, and SP3 have the different separation distances between the upper and lower reflective layers by the first wavelength selective layer 220c, the second wavelength selective layer 230c, and the third wavelength selective layer 240c, light of the different colors may be emitted in the sub-pixels SP1, SP2, and SP3 by the micro cavity effect. In addition, because the separation distances are different from each other by the first wavelength selective layer 220c, the second wavelength selective layer 230c, and the third wavelength selective layer 240c respectively disposed in the sub-pixels SP1, SP2, and SP3, a specific wavelength band may be selectively absorbed. Accordingly, a noise peak in a wavelength area other than a main emission peak in a target wavelength area may be removed.

Accordingly, purity of a color of light emitted at the main emission peak may be improved to improve the color reproduction rate, thereby providing a high-quality image to a user. This will be described later.

A plurality of first electrodes 241 may be disposed on the third insulating layer 224 and the third reflective electrode 240. The plurality of first electrodes 241 may be disposed in the sub-pixels SP1, SP2, and SP3, respectively.

In the third sub-pixel SP3, the third reflective electrode 240 may be disposed in contact with the rear surface of the first electrode 241, but the present disclosure may not be limited thereto. For example, an insulating layer may be further disposed on the third reflective electrode 240, and the plurality of first electrodes 241 may be disposed on the insulating layer. In this case, the third reflective electrode 240 and the first electrode 241 may be electrically connected to each other via an additional via electrode.

The plurality of third vias 235 extending through the third insulating layer 224 may be disposed to be spaced apart from each other. The plurality of third vias 235 may electrically connect the first electrodes 241 with the driving transistors TR thereunder, respectively. The third via 235 may include a metal material.

The bank 243 for distinguishing the sub-pixels SP1, SP2, and SP3 from each other may be disposed on the first electrode 241. The bank 243 may distinguish the light-emissive area EA and the non-light-emissive area NEA from each other, and may prevent the color mixing of light between the neighboring sub-pixels SP1, SP2, and SP3. The bank 243 may include an organic insulating layer made of polyimide or epoxy. In an example, the bank 243 may include one of a black resin, graphite, or black ink.

The trenches 244 to prevent a leakage current from occurring may be disposed between the adjacent sub-pixels SP1, SP2, and SP3. The trenches 244 may be constructed to have a concave shape in a thickness direction of the bank 243 in the boundary areas between the neighboring sub-pixels SP1, SP2, and SP3 and the third insulating layer 224.

The light-emissive layer 245 and the second electrode 247 may be sequentially disposed on the first electrode 241.

The light-emissive layer 245 may include an organic material that emits white light. The second electrode 247 may include a semi-transmissive metal material. For example, the second electrode 247 may include magnesium (Mg), silver (Ag), or an alloy of magnesium (Mg) and silver (Ag).

The light-emissive element may be formed to include the first electrode 241, the light-emissive layer 245, and the second electrode 247.

The encapsulating area 300 may be disposed on the second electrode 247. For example, the encapsulating area 300 may include a multi-layer structure including an inorganic insulating material and an organic insulating material. For example, the encapsulating area 300 may include a first inorganic encapsulation layer, a first organic encapsulation layer, and a second inorganic encapsulation layer, Alternatively, the encapsulation layer may include a first inorganic encapsulation layer, a first organic encapsulation layer, a second inorganic encapsulation layer, a second organic encapsulation layer, and a third inorganic encapsulation layer stacked sequentially.

The second substrate 350 may be disposed on the encapsulating area 300. The second substrate 350 may include a glass substrate or a plastic film, but the present disclosure may not be limited thereto.

In the display device according to another embodiment of the present disclosure, because the color filter is omitted, the encapsulating area 300 and one surface of the second substrate 350 may be disposed to be in contact with each other.

In the sub-pixels SP1, SP2, and SP3, the first to third reflective electrodes 220, 230, and 240 may be disposed to overlap the second electrode 247 in the vertical direction. For example, in the first sub-pixel SP1, the first reflective electrode 220 may be disposed to overlap the second electrode 247 in the vertical direction. In the second sub-pixel SP2, the second reflective electrode 230 may be disposed to overlap the second electrode 247 in the vertical direction. In the third sub-pixel SP3, the third reflective electrode 240 may be disposed to overlap the second electrode 247 in the vertical direction.

In the first sub-pixel SP1, the first reflective electrode 220 and the second electrode 247 are spaced apart from each other by a first distance, and in the second sub-pixel SP2, the second reflective electrode 230 and the second electrode 247 are spaced apart from each other by a second distance. In addition, in the third sub-pixel SP3, the third reflective electrode 240 and the second electrode 247 are spaced apart from each other by a third distance. In addition, the first distance, the second distance, and the third distance may be different from each other.

The micro cavity effect may be obtained between the second electrode 247 and the first reflective electrode 220, between the second electrode 247 and the second reflective electrode 230, and between the second electrode 247 and the third reflective electrode 240. Accordingly, light of the different colors may be emitted from the sub-pixels SP1, SP2, and SP3, respectively. For example, red light may be emitted from the first sub-pixel SP1, green light may be emitted from the second sub-pixel SP2, and blue light may be emitted from the third sub-pixel SP3.

The structure according to another embodiment of the present disclosure may be a strong micro cavity structure. Accordingly, a width of the emission spectrum may be reduced, and thus light in the specific wavelength area may be strongly emitted.

For example, some of light beams that reach the second electrode 247 among light beams generated from the light-emissive layer 245 may be reflected again and may travel toward the first to third reflective electrodes 220, 230, and 240.

The light beams reaching the first to third reflective electrodes 220, 230, and 240 may pass through the first to third upper reflective layers 220b, 230b, and 240b, may be reflected by the first to third lower reflective layers 220a, 230a, and 240a, and may travel toward the second electrode 247 again.

Thicknesses of the first to third lower reflective layers 220a, 230a, and 240a and the first to third upper reflective layers 220b, 230b, and 240b of the first to third reflective electrodes 220, 230, and 240 may be different from each other. For example, the first to third upper reflective layers 220b, 230b, and 240b disposed at locations relatively close to the second electrode 247 may be thinner than the first to third lower reflective layers 220a, 230a, and 240a such that light reflected from the second electrode 247 is transmitted therethrough. In addition, because the first to third lower reflective layers 220a, 230a, and 240a may be relatively thick because they should reflect light toward the second electrode 247.

The first to third wavelength selective layers 220c, 230c, and 240c may separate the first to third lower reflective layers 220a, 230a, and 240a and the first to third upper reflective layers 220b, 230b, and 240b from each other by the first to third distances D1, D2, and D3 different from each other in the sub-pixels SP1, SP2, and SP3, respectively.

Wavelength range areas offset in the sub-pixels SP1, SP2, and SP3 may be different from each other by the first to third distances D1, D2, and D3 of the first to third wavelength selective layers 220c, 230c, and 240c, which are different from each other. For example, in the first sub-pixel SP1 that emits red light, the first wavelength selective layer 220c may be disposed between the first lower reflective layer 220a and the first upper reflective layer 220b to offset a green wavelength range area and a blue wavelength range area. In the second sub-pixel SP2 that emits green light, the second wavelength selective layer 230c may be disposed between the first lower reflective layer 230a and the first upper reflective layer 230b to offset a red wavelength range area and the blue wavelength range area. In the third sub-pixel SP3 that emits blue light, the third wavelength selective layer 240c may be disposed between the first lower reflective layer 240a and the first upper reflective layer 240b to offset the red wavelength range area and the green wavelength range area.

Light in remaining wavelength ranges except for light in the wavelength ranges of the target colors determined by the first to third wavelength selective layers 220c, 230c, and 240c may not be emitted to the outside via destructive interference between the first to third upper reflective layers 220b, 230b, and 240b and the first to third lower reflective layers 220a, 230a, and 240a.

In addition, light in the wavelength range of the target color may travel to the second electrode 247 and be emitted to the outside via constructive interference between the first to third upper reflective layers 220b, 230b, and 240b and the first to third lower reflective layers 220a, 230a, and 240a.

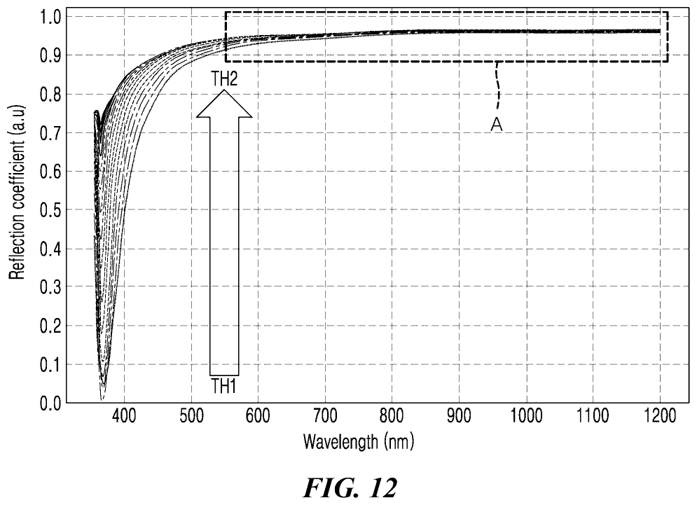

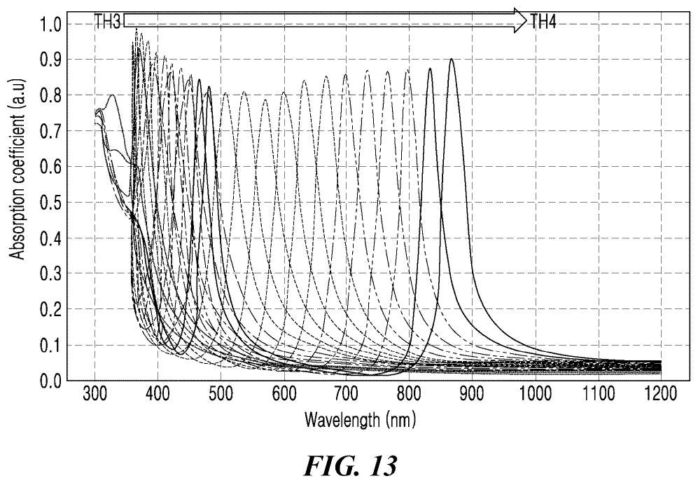

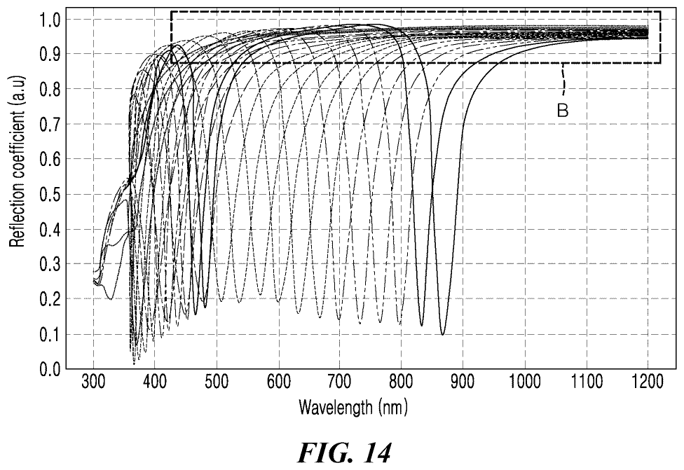

FIGS. 11 and 12 are graphs respectively showing light absorptivity and reflectivity based on a thickness of an upper reflective layer of a reflective electrode. Further, FIGS. 13 and 14 are graphs showing light absorptivity and reflectivity based on a thickness of a wavelength selective layer of a reflective electrode. In FIGS. 11 and 13, a horizontal axis represents a wavelength (nm) of light, and a vertical axis represents an absorption coefficient as a relative value. The closer the absorption coefficient is to 1.0, the greater the degree of absorption, and the closer it is to 0, the smaller the degree of absorption. In FIGS. 12 and 14, a horizontal axis represents a wavelength (nm) of light, and a vertical axis represents a reflection coefficient as a relative value. The closer the reflection coefficient is to 1.0, the greater the degree of reflection, and the closer it is to 0, the smaller the degree of reflection.

FIGS. 11 and 12 are an absorption spectrum (FIG. 11) and a reflection spectrum (FIG. 12) based on a change in thickness of an upper reflective layer in a state in which a wavelength selective layer and a lower reflective layer are fixed in a reflective electrode composed of a stacked structure of the upper reflective layer, the wavelength selective layer, and the lower reflective layer. For example, the upper reflective layer may be the first to third upper reflective layers 220b, 230b, and 240b, the wavelength selective layer may be the first to third wavelength selective layers 220c, 230c, and 240c, and the lower reflective layer may be the first to third lower reflective layers 220a, 230a, and 240a.

Referring to FIGS. 11 and 12, the absorptivity increases from a relatively great first thickness TH1 to a relatively small second thickness TH2 of the upper reflective layer of the reflective electrode. The first thickness TH1 may be 20 nm, and the second thickness TH2 may be 100 nm. When the thickness of the upper reflective layer is greater than 100 nm, as the absorption coefficient approaches zero, all light may be reflected without being absorbed. In addition, the reflectivity does not change in an area ‘A’ other than an absorption area. Accordingly, the absorptivity of light may be selected by adjusting the thickness of the upper reflective layer.

FIGS. 13 and 14 are an absorption spectrum (FIG. 13) and a reflection spectrum (FIG. 14) based on a case in which a thickness of a wavelength selective layer is changed in a state in which an upper reflective layer and a lower reflective layer are fixed in a reflective electrode composed of a stacked structure of the upper reflective layer, the wavelength selective layer, and the lower reflective layer.

Referring to FIGS. 13 and 14, it may be seen that as the thickness of the wavelength selective layer changes between a first thickness TH3 and a second thickness TH4, a wavelength range absorbed by the upper reflective layer changes. In addition, even when the thickness of the wavelength selective layer is changed, a change rate does not change as in an area ‘B’. Accordingly, a range of a wavelength area to be absorbed may be selected by adjusting the thickness of the wavelength selective layer.

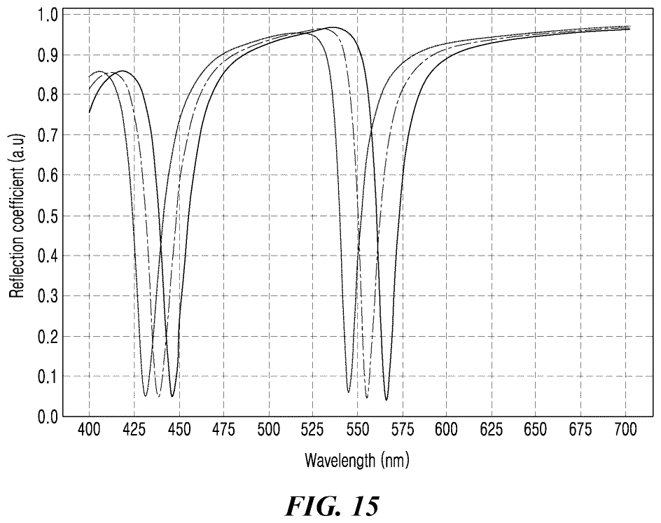

FIGS. 15 to 20 are graphs showing light reflectivity and absorptivity of respective sub-pixels according to another embodiment of the present disclosure.

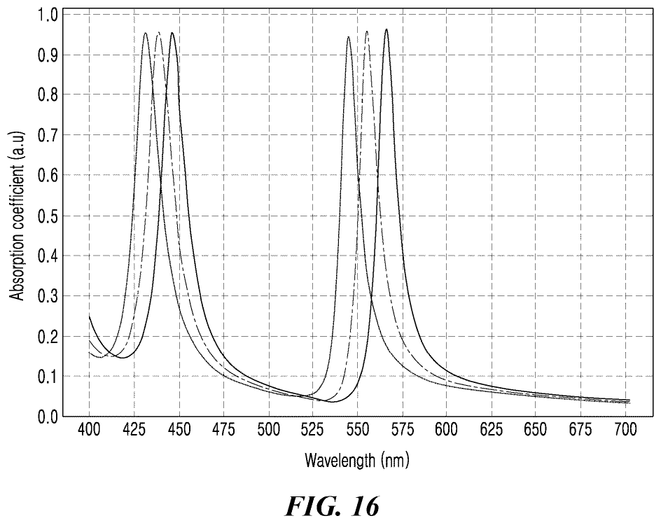

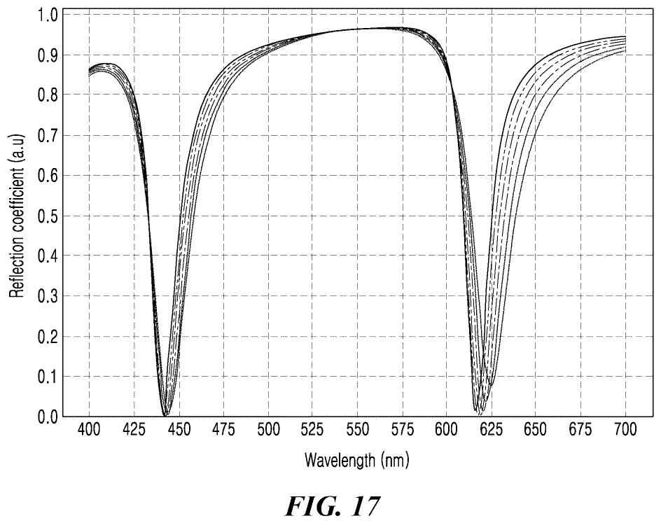

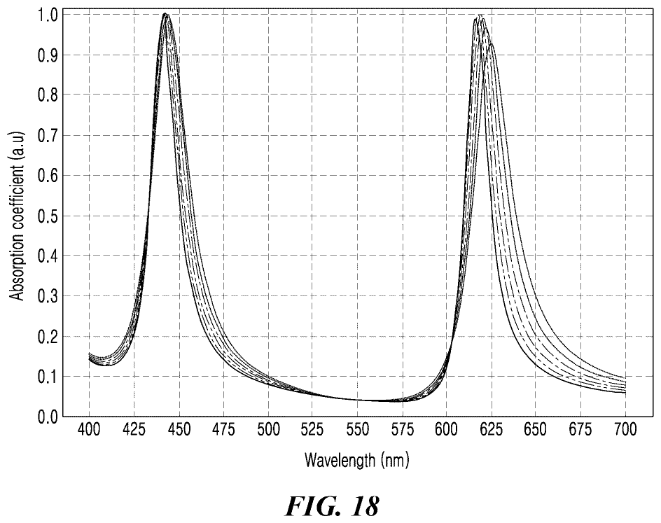

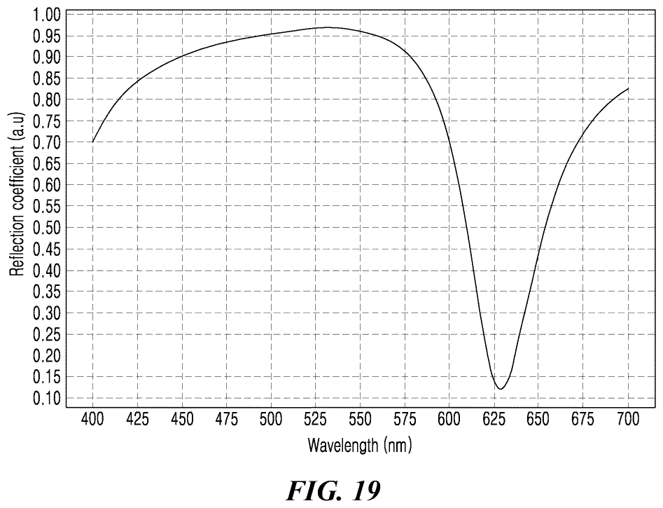

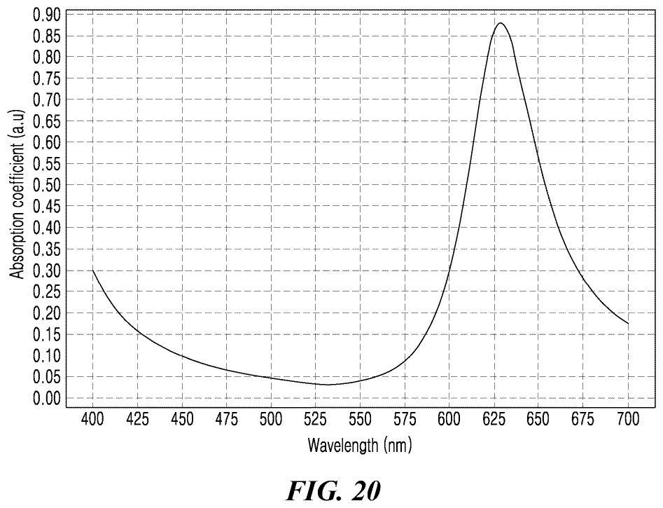

FIGS. 15 and 16 are graphs showing light reflectivity and absorptivity of a first sub-pixel. FIGS. 17 and 18 are graphs showing light reflectivity and absorptivity of a second sub-pixel. Further, FIGS. 19 and 20 are graphs showing light reflectivity and absorptivity of a third sub-pixel. In FIGS. 15, 17, and 19, a horizontal axis represents a wavelength (nm) of light, and a vertical axis represents a reflection coefficient as a relative value. In FIGS. 16, 18, and 20, a horizontal axis represents a wavelength (nm) of light, and a vertical axis represents an absorption coefficient as a relative value.

Referring to FIGS. 15 and 16, the first wavelength selective layer 220c is disposed such that the first distance D1 between the first lower reflective layer 220a and the first upper reflective layer 220b in the first sub-pixel is in a range of 390 nm to 410 nm. It may be seen that as the reflectivity is close to 1 at the wavelength of 600 nm to 670 nm, which is the wavelength area of red light, red light is reflected and emitted from the first sub-pixel. In addition, it may be seen that as other wavelength range areas except for the wavelength range area of red light have an absorptivity of 0, light is absorbed by the first upper reflective layer 220b and is not emitted to the outside. In addition, an area having reflectivity in a range of 450 nm to 550 nm does not emit light because of the destructive interference.

Referring to FIGS. 17 and 18, the second wavelength selective layer 230c is disposed such that the second distance D2 between the second lower reflective layer 230a and the second upper reflective layer 230b in the second sub-pixel is in a range of 280 nm to 300 nm. It may be seen that as the reflectivity is close to 1 at the wavelength of 495 nm to 570 nm, which is the wavelength area of green light, green light is reflected and emitted from the second sub-pixel. In addition, it may be seen that as other wavelength range areas except for the wavelength range area of green light have an absorptivity of 0, light is absorbed by the second upper reflective layer 230b and is not emitted to the outside. In addition, an area having reflectivity in a remaining area except for the wavelength area of green light does not emit light because of the destructive interference.

Referring to FIGS. 19 and 20, the third wavelength selective layer 240c is disposed such that the third distance D3 between the third lower reflective layer 240a and the third upper reflective layer 240b in the third sub-pixel is in a range of 110 nm to 130 nm. It may be seen that as the reflectivity increases at the wavelength 450 nm to 495 nm, which is a long wavelength portion of the wavelength area of blue light, blue light is reflected and emitted from the third sub-pixel. In addition, it may be seen that as other wavelength range areas except for the wavelength range area of blue light has an absorptivity of 0, light is absorbed by the third upper reflective layer 240b and is not emitted to the outside. In addition, an area having reflectivity in a remaining area except for the wavelength area of blue light does not emit light because of the destructive interference. In addition, blue light in a short wavelength range of 300 nm to 400 nm may be selectively removed. In a head mounted display product that affects retina as an entirety of light enters user's eyes, blue light in the short wavelength range of 300 nm to 400 nm, which may degrade a function of the retina may be blocked by adjusting the third wavelength selective layer 240c.

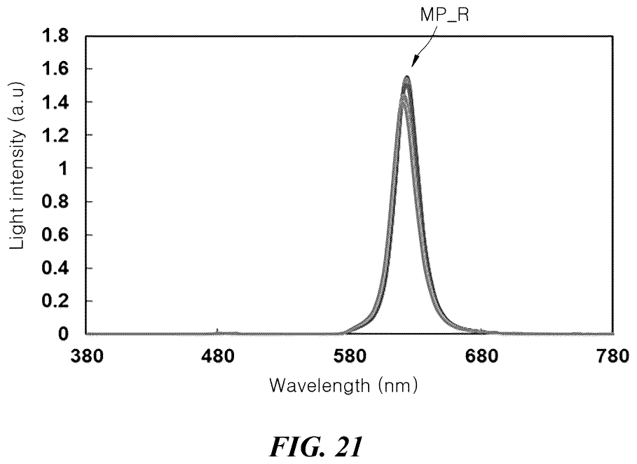

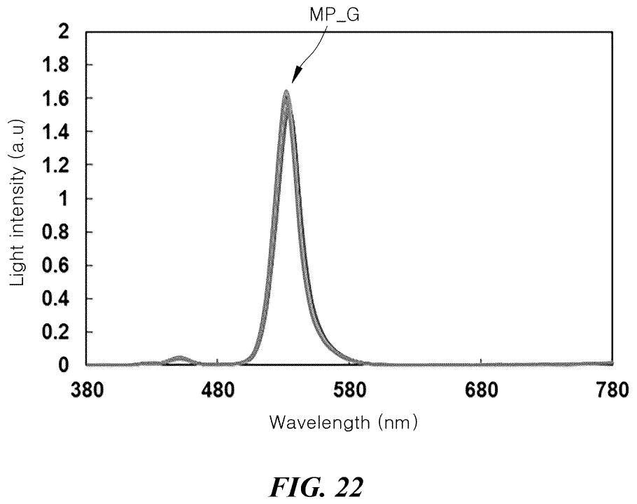

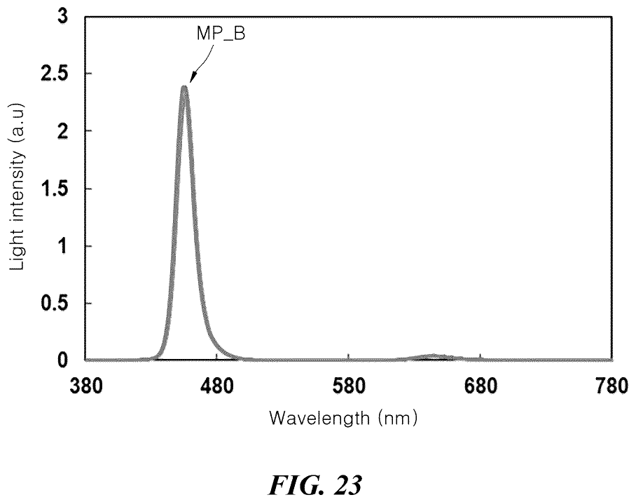

FIGS. 21 to 23 are diagrams illustrating emission spectra of respective sub-pixels according to another embodiment of the present disclosure. FIG. 21 illustrates an emission spectrum of a first sub-pixel. FIG. 22 illustrates an emission spectrum of a second sub-pixel. FIG. 23 illustrates an emission spectrum of a third sub-pixel. In FIGS. 21 to 23, a horizontal axis represents a wavelength (nm) of light, and a vertical axis represents intensity of light. The intensity of light is a relative value based on a maximum value of the emission spectrum.

Referring to FIG. 21, it may be seen that light emitted from the first sub-pixel has only a main emission peak MP_R at a wavelength of 600 nm to 670 nm. Accordingly, red light may be emitted from the first sub-pixel. Referring to FIG. 22, it may be seen that light emitted from the second sub-pixel has only a main emission peak MP_G at a wavelength of 495 nm to 570 nm. Accordingly, green light may be emitted from the second sub-pixel. Further, referring to FIG. 23, it may be seen that light emitted from the third sub-pixel only has a main emission peak MP_B at a wavelength of 450 nm to 495 nm. Accordingly, blue light may be emitted from the third sub-pixel.

Referring to FIGS. 21 to 23, it may be seen that, in the display device according to another embodiment of the present disclosure, the noise peak does not occur in an area other than the main emission peak MP_R, MP_G, and MP_B in each of the first to third sub-pixels.

Accordingly, purity of the colors of light emitted from the first sub-pixel, the second sub-pixel, and the third sub-pixel may be improved. For example, because the main emission peaks MP_R, MP_G, and MP_B of the respective first to third sub-pixels are implemented in a narrow and pointed shape, contamination caused by adjacent colors does not occur, so that light may be emitted with the high purity colors. Therefore, because an image may be displayed in a color closer to nature, user's immersion may be further improved.

According to another embodiment of the present disclosure, the reflective electrode disposed in each sub-pixel may be formed in the multi-layer structure including the lower reflective layer, the wavelength selective layer, and the upper reflective layer, and the separation distance between the lower reflective layer and the upper reflective layer may be adjusted by the thickness of the wavelength selective layer. In addition, the lower reflective layer and the upper reflective layer may be disposed to have the different thicknesses.

Accordingly, because light in the remaining wavelength range except for light in the wavelength range of the target color to be emitted from each sub-pixel may be absorbed by adjusting the thickness of the upper reflective layer, emission thereof to the outside may be prevented. In addition, light in the remaining wavelength range except for light in the wavelength range of the target color may be prevented from being emitted to the outside by the destructive interference. Accordingly, the purity of the color may be improved.

In addition, because the distance between the lower reflective layer and the upper reflective layer may be adjusted to selectively emit light of the specific wavelength by the distance between the reflective electrode and the second electrode (or the cathode electrode), the color filter may be omitted. Accordingly, because an expensive semiconductor exposure device is not applied, a cost of a final product may be reduced. In addition, by omitting the color filter, process optimization may be implemented by simplifying a process method. In addition, because the color filter may be omitted, light may be prevented from being lost while passing through the color filter, thereby improving light efficiency.

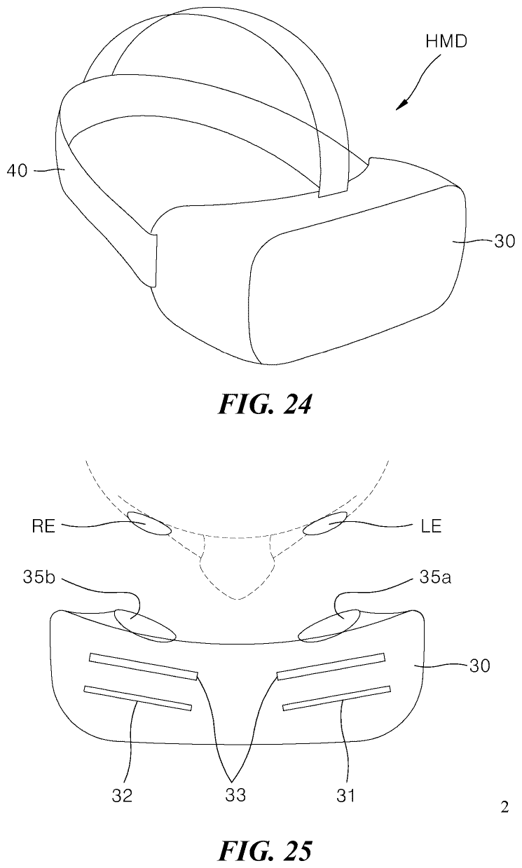

FIGS. 24 to 26 are diagrams of a head-mounted display apparatus including a display device according to an embodiment of the present disclosure

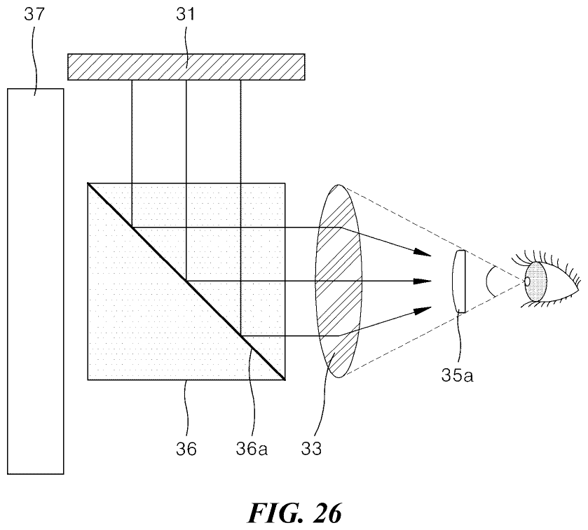

FIGS. 24 to 26 are diagrams of a head-mounted display apparatus including a display device according to an embodiment of the present disclosure. Specifically, FIG. 24 is a schematic perspective view of a head-mounted display apparatus including a display device according to an embodiment of the present disclosure, and FIG. 25 is a top view showing a head-mounted display apparatus implementing virtual reality. FIG. 26 is a side view showing a head-mounted display apparatus that implements augmented reality.

Referring to FIG. 24, the head-mounted display apparatus HMD including a display device according to an embodiment of the present disclosure may include a casing 30 and a head mounting band 40.

The casing 30 may receive therein components such as a display device, a lens array, an eyepiece, a sound device, an accelerometer, and a position sensor, etc. The head mounting band 40 is fixed to the casing 30. The head mounting band 20 is illustrated as being formed to surround an upper surface and both opposing side surfaces of the user's head. However, embodiments of the present disclosure are not limited thereto. The head mounting band 40 is used to secure the head-mounted display apparatus HMD to the user's head. In another example, the head mounting band 40 may be embodied as an eyeglass frame or a helmet-shaped structure that entirely surrounds the user's head.

The head-mounted display apparatus HMD may include the display device according to an embodiment of the present disclosure as described in FIG. 3 and FIG. 7, and may provide an image implementing virtual reality (VR) or an image implementing augmented reality (AR) to the user.

Referring to FIG. 25, the head-mounted display apparatus that implements virtual reality may include a display device 31 for a left-eye, a display device 32 for a right-eye, a lens array 33, and a left-eye eyepiece 35a and a right-eye eyepiece 35b. The display device 31 for a left-eye and the display device 32 for right-eye, the lens array 33, and the left-eye eyepiece 35a and the right-eye eyepiece 35b may be received in the casing 30.

The display device 31 for a left-eye and the display device 32 for a right-eye may display the same image. When the display device 31 for a left-eye and the display device 32 for a right-eye display the same image, the user may view the 2D image through the head-mounted display apparatus. Alternatively, the display device 31 for a left-eye may display an image for a left-eye, and the display device 32 for a right-eye may display an image for a right-eye that is different from the image for a left-eye. In this case, the user may view a three-dimensional image through the head-mounted display apparatus. Each of the display device 31 for a left-eye and the display device 32 for a right-eye may include the display device according to FIG. 4 or FIG. 7 as described above.

One of the lens array 33 may be spaced apart from each of the left-eye eyepiece 35a and the display device for a left-eye 31, and may be disposed between the left-eye eyepiece 35a and the display device for a left-eye 31. That is, one of the lens array 33 may be located in front of the left-eye eyepiece 35a and in rear of the display device for a left-eye 31. Furthermore, the other of the lens array 33 may be spaced away from each of the right-eye eyepiece 35b and the display device for a right-eye 32, and may be disposed between the right-eye eyepiece 35b and the display device for a right-eye 32. That is, the other of the lens array 33 may be located in front of the right-eye eyepiece 35b and in rear of the display device for a right-eye 32.

The lens array 33 may include, but is not limited to, a micro lens array. In one example, the lens array 33 may include a pin hole array. The image displayed from the display device for a left-eye 31 or the display device for a right-eye 32 may be visible to the user in an enlarged manner due to the lens array 33. The user's left-eye LE may be located in rear of the left-eye eyepiece 35a, and the user's right-eye RE may be located in rear of the right-eye eyepiece 35b.

Referring to FIG. 26, the head-mounted display apparatus that implements augmented reality includes the display device for a left-eye 31, the lens array 33, the left-eye eyepiece 35a, a transmissive and reflective portion 36, and a transmissive window 37. For convenience of illustration, FIG. 26 shows only a configuration related to the left-eye, and a configuration related to the right-eye is the same or similar to the configuration related to the left-eye. Additionally, the same drawing symbols as in FIG. 25 may represent the same components in FIG. 26.

The display device for a left-eye 31, the lens array 33, the left-eye eyepiece 35a, the transmissive and reflective portion 36, and the transmissive window 37 are housed in casing 30 (see FIG. 24). The display device for a left-eye 31 may be disposed on one side of the transmissive and reflective portion 36, for example, on an upper side thereof so that the display device for a left-eye 31 does not block the transmissive window 37. Accordingly, the display device for a left-eye 31 may provide an image to the transmissive and reflective portion 36 without blocking an external background visible through the transmissive window 37.

The display device 31 for a left-eye may include the display device according to one embodiment of the present disclosure as shown in FIG. 3 or FIG. 7. The lens array 33 may be provided between the left-eye eyepiece 35a and the transmissive and reflective portion 36. The user's left-eye may be located in rear of the left-eye eyepiece 35a.

The transmissive and reflective portion 36 is disposed between the lens array 33 and the transmissive window 37. The transmissive and reflective portion 36 may include a transmissive and reflective surface 36a that transmits a portion of light therethrough and reflects the other portion of light therefrom. The transmissive and reflective surface 36a includes a semi-transmissive metal film. For example, the semi-transmissive metal film may be made of a semi-transmissive metal material such as magnesium (Mg), silver (Ag), or an alloy of magnesium (Mg) and silver (Ag). The transmissive and reflective surface 36a may be formed to allow the image displayed from the display device for a left-eye 31 to be directed to the lens array 33.

Therefore, the user may view both the external background visible through the transmissive window 37 and the image displayed from the display device for a left-eye 31. In other words, the user may view both the real background and the virtual image as one image in an overlapping manner. Thus, the augmented reality may be implemented.

The display device according to various aspects and embodiments of the present disclosure may be described as follows.

A first aspect of the present disclosure provides a display device including a first substrate including a plurality of sub-pixels areas corresponding to a plurality of sub-pixels, each first electrode disposed on the substrate and in each of the sub-pixels, a light-emissive layer disposed on the first electrode, a second electrode disposed on the light-emissive layer, and each reflective electrode disposed on the substrate and in each of the sub-pixels, wherein the reflective electrodes have different thicknesses in the respective sub-pixels.

In accordance with some embodiments of the first aspect of the present disclosure, the display device may further include an encapsulating area disposed on the second electrode, and a second substrate disposed on the encapsulating area, and the encapsulating area and one surface of the second substrate may be in contact with each other.

In accordance with some embodiments of the first aspect of the present disclosure, each reflective electrode may include a lower reflective layer, an upper reflective layer spaced apart from the lower reflective layer, and a wavelength selective layer disposed between the lower reflective layer and the upper reflective layer.

In accordance with some embodiments of the first aspect of the present disclosure, the lower reflective layer and the upper reflective layer may have different thicknesses.

In accordance with some embodiments of the first aspect of the present disclosure, the lower reflective layer may have a first thickness, and the upper reflective layer may have a second thickness, and the second thickness may be smaller than the first thickness.

In accordance with some embodiments of the first aspect of the present disclosure, the wavelength selective layers may have different thicknesses in the respective sub-pixels.

In accordance with some embodiments of the first aspect of the present disclosure, the sub-pixels may include a first sub-pixel that emits light of a first color, a second sub-pixel that emits light of a second color different from the first color, and a third sub-pixel that emits light of a third color different from the first color and the second color, and among the reflective electrodes, a reflective electrode in the first sub-pixel may have a greatest thickness and a reflective electrode in the third sub-pixel may have a smallest thickness.

In accordance with some embodiments of the first aspect of the present disclosure, the reflective electrodes may include a first reflective electrode disposed in the first sub-pixel, and having a first lower reflective layer, a first wavelength selective layer, and a first upper reflective layer disposed in an upward direction (or ‘stacked in sequence’ or ‘stacked in order’), a second reflective electrode disposed in the second sub-pixel, and having a second lower reflective layer, a second wavelength selective layer, and a second upper reflective layer disposed in the upward direction, and a third reflective electrode disposed in the third sub-pixel, and having a third lower reflective layer, a third wavelength selective layer, and a third upper reflective layer disposed in the upward direction.

In accordance with some embodiments of the first aspect of the present disclosure, the first lower reflective layer and the first upper reflective layer may be spaced apart from each other by a first distance of the first wavelength selective layer, and the first distance may select a wavelength range of light of a color different from the first color.

In accordance with some embodiments of the first aspect of the present disclosure, light of the first color may have a wavelength in a range of 600 nm to 670 nm, and the first distance may be in a range of 390 nm to 410 nm.

In accordance with some embodiments of the first aspect of the present disclosure, the second lower reflective layer and the second upper reflective layer may be spaced apart from each other by a second distance of the second wavelength selective layer, and the second distance may select a wavelength range of light of a color different from the second color.

In accordance with some embodiments of the first aspect of the present disclosure, light of the second color may have a wavelength in a range of 495 nm to 570 nm, and the second distance may be in a range of 280 nm to 300 nm.

In accordance with some embodiments of the first aspect of the present disclosure, the third lower reflective layer and the third upper reflective layer may be spaced apart from each other by a third distance of the third wavelength selective layer, and the third distance may select a wavelength range of light of a color different from the third color.

In accordance with some embodiments of the first aspect of the present disclosure, light of the third color may have a wavelength in a range of 450 nm to 495 nm, and the third distance may be in a range of 110 nm to 130 nm.

In accordance with some embodiments of the first aspect of the present disclosure, the first lower reflective layer may have a first thickness, and the first upper reflective layer may have a second thickness smaller than the first thickness, and the first upper reflective layer may absorb light in a wavelength range of a color different from the first color, and the second thickness may be a thickness in a range of 5 nm to 45 nm.

In accordance with some embodiments of the first aspect of the present disclosure, the second lower reflective layer may have a first thickness, and the second upper reflective layer may have a second thickness smaller than the first thickness, and the second upper reflective layer may absorb light in a wavelength range of a color different from the second color, and the second thickness may be a thickness in a range of 5 nm to 45 nm.

In accordance with some embodiments of the first aspect of the present disclosure, the third lower reflective layer may have a first thickness, and the third upper reflective layer may have a second thickness smaller than the first thickness, and the third upper reflective layer may absorb light in a wavelength range of a color different from the third color, and the second thickness may be a thickness in a range of 5 nm to 45 nm.

In accordance with some embodiments of the first aspect of the present disclosure, the lower reflective layer and the upper reflective layer may include silver (Ag), a silver alloy, aluminum (Al), or an aluminum alloy, and the wavelength selective layer may include an inorganic insulating material, an organic insulating material, a polymer, or a monomer.

A second aspect of the present disclosure provides a display device including a first substrate including first to third sub-pixels that emit light of different colors, respectively, each first electrode disposed in each of the first to third sub-pixels, a light-emissive layer disposed on the first electrode, a second electrode disposed on the light-emissive layer, and first to third reflective electrodes respectively disposed in the first to third sub-pixels, wherein each of the first to third reflective electrodes includes a lower reflective layer, a wavelength selective layer, and an upper reflective layer, wherein the lower reflective layer and the upper reflective layer have different thicknesses, wherein the second electrode and the first reflective electrode are disposed to be spaced apart from each other by a first distance in the first sub-pixel, the second electrode and the second reflective electrode are disposed to be spaced apart from each other by a second distance different from the first distance in the second sub-pixel, and the second electrode and the third reflective electrode are disposed to be spaced apart from each other by a third distance different from the first distance and the second distance in the third sub-pixel.

In accordance with some embodiments of the second aspect of the present disclosure, the display device may further include an encapsulating area disposed on the second electrode, and a second substrate disposed on the encapsulating area, and the encapsulating area and one surface of the second substrate may be in contact with each other.

In accordance with some embodiments of the second aspect of the present disclosure, the lower reflective layer may have a first thickness, and the upper reflective layer may have a second thickness, and the second thickness may be smaller than the first thickness.

In accordance with some embodiments of the second aspect of the present disclosure, the wavelength selective layers may have different thicknesses in the respective first to third sub-pixels.

Although some embodiments of the present disclosure have been described above with reference to the accompanying drawings, the present disclosure may not be limited to some embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some embodiments as described above are not restrictive but illustrative in all respects.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a first substrate including a plurality of sub-pixels areas corresponding to a plurality of sub-pixels;
a first electrode disposed on the substrate in each of the sub-pixels;
a light-emissive layer disposed on the first electrode;
a second electrode disposed on the light-emissive layer; and
reflective electrodes disposed on the substrate and in each of the sub-pixels,
wherein the reflective electrodes respectively disposed in the sub-pixels have different thicknesses.

2. The display device of claim 1, further comprising:
an encapsulating area disposed on the second electrode; and
a second substrate disposed on the encapsulating area,
wherein the encapsulating area and one surface of the second substrate are in contact with each other.

3. The display device of claim 1, wherein each of the reflective electrodes includes:
a lower reflective layer;
an upper reflective layer spaced apart from the lower reflective layer; and
a wavelength selective layer disposed between the lower reflective layer and the upper reflective layer.

4. The display device of claim 3, wherein the lower reflective layer and the upper reflective layer have different thicknesses.

5. The display device of claim 4, wherein the lower reflective layer has a first thickness, and the upper reflective layer has a second thickness, and
wherein the second thickness is smaller than the first thickness.

6. The display device of claim 3, wherein the wavelength selective layers in the respective sub-pixels have different thicknesses.

7. The display device of claim 1, wherein the plurality of sub-pixels include:
a first sub-pixel configured to emit light of a first color;
a second sub-pixel configured to emit light of a second color different from the first color; and
a third sub-pixel configured to emit light of a third color different from the first color and the second color,
wherein among distances between the reflective electrodes of the plurality of sub-pixels and the second electrode, a distance between a reflective electrode in the first sub-pixel and the second electrode is greatest, and a distance between a reflective electrode in the third sub-pixel and the second electrode is smallest.

8. The display device of claim 1, wherein the plurality of sub-pixels include:
a first sub-pixel configured to emit light of a first color;
a second sub-pixel configured to emit light of a second color different from the first color; and
a third sub-pixel configured to emit light of a third color different from the first color and the second color,
wherein among the reflective electrodes, a reflective electrode in the first sub-pixel has a greatest thickness and a reflective electrode in the third sub-pixel has a smallest thickness.

9. The display device of claim 7, wherein the reflective electrodes include:
a first reflective electrode disposed in the first sub-pixel, and having a first lower reflective layer, a first wavelength selective layer, and a first upper reflective layer stacked in sequence;
a second reflective electrode disposed in the second sub-pixel, and having a second lower reflective layer, a second wavelength selective layer, and a second upper reflective layer stacked in sequence; and
a third reflective electrode disposed in the third sub-pixel, and having a third lower reflective layer, a third wavelength selective layer, and a third upper reflective layer stacked in sequence.

10. The display device of claim 9, wherein the first lower reflective layer and the first upper reflective layer are spaced apart from each other by a first distance of the first wavelength selective layer, and
wherein the first distance selects a wavelength range that excludes the wavelength range corresponding to the first color.

11. The display device of claim 10, wherein light of the first color has a wavelength in a range of 600 nm to 670 nm, and the first distance is in a range of 390 nm to 410 nm.

12. The display device of claim 9, wherein the second lower reflective layer and the second upper reflective layer are spaced apart from each other by a second distance of the second wavelength selective layer, and
wherein the second distance selects a wavelength range that excludes the wavelength range corresponding to the second color.

13. The display device of claim 12, wherein light of the second color has a wavelength in a range of 495 nm to 570 nm, and the second distance is in a range of 280 nm to 300 nm.

14. The display device of claim 9, wherein the third lower reflective layer and the third upper reflective layer are spaced apart from each other by a third distance of the third wavelength selective layer, and
wherein the third distance selects a wavelength range that excludes the wavelength range corresponding to the third color.

15. The display device of claim 14, wherein light of the third color has a wavelength in a range of 450 nm to 495 nm, and the third distance is in a range of 110 nm to 130 nm.

16. The display device of claim 9, wherein the first lower reflective layer has a first thickness, and the first upper reflective layer has a second thickness smaller than the first thickness, and
wherein the first upper reflective layer absorbs light in a wavelength range of a color different from the first color, and the second thickness is a thickness in a range of 5 nm to 45 nm.

17. The display device of claim 9, wherein the second lower reflective layer has a first thickness, and the second upper reflective layer has a second thickness smaller than the first thickness, and
wherein the second upper reflective layer absorbs light in a wavelength range of a color different from the second color, and the second thickness is a thickness in a range of 5 nm to 45 nm.

18. The display device of claim 9, wherein the third lower reflective layer has a first thickness, and the third upper reflective layer has a second thickness smaller than the first thickness, and
wherein the third upper reflective layer absorbs light in a wavelength range of a color different from the third color, and the second thickness is a thickness in a range of 5 nm to 45 nm.

19. The display device of claim 3, wherein the lower reflective layer and the upper reflective layer include silver (Ag), a silver alloy, aluminum (Al), or an aluminum alloy, and
wherein the wavelength selective layer includes an inorganic insulating material, an organic insulating material, a polymer, or a monomer.

20. A display device comprising:
a first substrate including first to third sub-pixel areas corresponding to first to third sub-pixels configured to emit light of different colors, respectively;
a first electrode disposed on the substrate in each of the first to third sub-pixels;
a light-emissive layer disposed on the first electrode;
a second electrode disposed on the light-emissive layer; and
first to third reflective electrodes respectively disposed in the first to third sub-pixels,
wherein each of the first to third reflective electrodes includes a lower reflective layer, a wavelength selective layer, and an upper reflective layer,
wherein the lower reflective layer and the upper reflective layer have different thicknesses,
wherein the second electrode and the first reflective electrode are disposed to be spaced apart from each other by a first distance in the first sub-pixel, the second electrode and the second reflective electrode are disposed to be spaced apart from each other by a second distance different from the first distance in the second sub-pixel, and the second electrode and the third reflective electrode are disposed to be spaced apart from each other by a third distance different from the first distance and the second distance in the third sub-pixel.

21. The display device of claim 20, further comprising:
an encapsulating area disposed on the second electrode; and
a second substrate disposed on the encapsulating area,
wherein the encapsulating area and one surface of the second substrate are in contact with each other.

22. The display device of claim 20, wherein the lower reflective layer has a first thickness, and the upper reflective layer has a second thickness, and
wherein the second thickness is smaller than the first thickness.

23. The display device of claim 20, wherein the wavelength selective layers in the respective first to third sub-pixels have different thicknesses respectively.
